(19) United States
(12) Patent Application Publication
(10) Pub. No.: US 2014/0332816 A1
(43) Pub. Date: Nov. 13, 2014

(54) SEMICONDUCTOR DEVICE

(71) Applicant: KABUSHIKI KAISHA TOSHIBA, Tokyo (JP)

(72) Inventor: Wataru SAKAMOTO, Mie (JP)

(73) Assignee: KABUSHIKI KAISHA TOSHIBA, Tokyo (JP)

(21) Appl. No.: 14/175,638

(22) Filed: Feb. 7, 2014

(30) Foreign Application Priority Data
May 8, 2013 (JP) 2013-098395

(51) Int. Cl. H01L 27/115; H01L 29/04

(52) U.S. Cl. CPC H01L 27/115; H01L 29/04
USPC 257/71; 257/66

(57) ABSTRACT

A semiconductor device includes a first insulating film formed on a memory cell region of the semiconductor substrate, a first polysilicon layer formed on the first insulating film, and memory cell transistors formed on the first polysilicon layer, each including a charge storage layer, an inter-electrode insulating film and a control gate electrode. The semiconductor device further includes a laminated structure formed on a peripheral circuit region of the semiconductor substrate that includes a second insulating film, a second polysilicon layer, a third insulating film, a third polysilicon layer, a fourth insulating film formed from the same material as a material of the inter-electrode insulating film, and a first electrode formed from the same material as a material of the control gate electrode. The third polysilicon layer, the fourth insulating film, and the first electrode are arranged in the peripheral circuit region to form a capacitance element.

### CROSS-REFERENCE TO RELATED APPLICATION

This application is based upon and claims the benefit of priority from Japanese Patent Application No. 2013-098395, filed May 8, 2013, the entire contents of which are incorporated herein by reference.

### FIELD

Embodiments described herein relate generally to a semiconductor device.

### BACKGROUND

A NAND-type flash memory device which includes a memory cell region having a Silicon On Insulator (SOI) structure, and in which upper surfaces of oxide films in the memory cell region and a peripheral circuit region are formed to have the same height, is known in the art. In such a configuration, the memory cell region may be prepared using solid-phase epitaxial growth, in which case openings are necessary in the substrate and the active region. In addition, a Shallow Trench Isolation (STI) process is performed on both the memory cell region and the peripheral circuit region. When the STI formed in the memory cell region is deep and an active region which includes a fine width (for example, 30 nm or less) is formed to achieve high integration, mechanical strength is deteriorated and the collapse or twisting of a pattern in the active region may occur.

### DESCRIPTION OF THE DRAWINGS

FIG. 1 is an example of an equivalent circuit diagram illustrating a part of the memory cell array of a NAND-type flash memory device according to a first embodiment.

FIG. 2 is an example of a schematic plan view illustrating a layout pattern of a part of a memory cell region.

FIG. 3 is an example of a schematic plan view illustrating a layout pattern of a part of a peripheral circuit region.

FIG. 4A is an example of a schematic cross-sectional view taken along a line A-A in FIG. 2, and FIG. 4B is an example of a schematic cross-sectional view taken along a line B-B in FIG. 2.

FIGS. 5A and 5B illustrate a structure of a gate electrode of the peripheral transistor of a low voltage system in the peripheral circuit region, where FIG. 5A is an example of a schematic cross-sectional view taken along a line C-C in FIG. 3, and FIG. 5B is an example of a schematic cross-sectional view taken along a line D-D in FIG. 3.

FIGS. 6A and 6B illustrate a structure of the gate electrode of the peripheral transistor of a high voltage system in the peripheral circuit region, where FIG. 6A is an example of a schematic cross-sectional view taken along a line C-C in FIG. 3, and FIG. 6B is an example of a schematic cross-sectional view taken along a line D-D in FIG. 3.

FIG. 7A is a view corresponding to FIG. 4A during the process of manufacturing (part 1), FIG. 7B is a view corresponding to FIG. 5A during the process of manufacturing (part 1), and FIG. 7C is a view corresponding to FIG. 6A during the process of manufacturing (part 1).

FIG. 8A is a view corresponding to FIG. 4A during the process of manufacturing (part 2), FIG. 8B is a view corresponding to FIG. 5A during the process of manufacturing (part 2), and FIG. 8C is a view corresponding to FIG. 6A during the process of manufacturing (part 2).

FIG. 9A is a view corresponding to FIG. 4A during the process of manufacturing (part 3), FIG. 9B is a view corresponding to FIG. 5A during the process of manufacturing (part 3), and FIG. 9C is a view corresponding to FIG. 6A during the process of manufacturing (part 3).

FIG. 10A is a view corresponding to FIG. 4A during the process of manufacturing (part 4), FIG. 10B is a view corresponding to FIG. 5A during the process of manufacturing (part 4), and FIG. 10C is a view corresponding to FIG. 6A during the process of manufacturing (part 4).

FIG. 11A is a view corresponding to FIG. 4A during the process of manufacturing (part 5), FIG. 11B is a view corresponding to FIG. 5A during the process of manufacturing (part 5), and FIG. 11C is a view corresponding to FIG. 6A during the process of manufacturing (part 5).

FIG. 12A is a view corresponding to FIG. 4A during the process of manufacturing (part 6), FIG. 12B is a view corresponding to FIG. 5A during the process of manufacturing (part 6), and FIG. 12C is a view corresponding to FIG. 6A during the process of manufacturing (part 6).

FIG. 13A is a view corresponding to FIG. 4A during the process of manufacturing (part 7), FIG. 13B is a view corresponding to FIG. 5A during the process of manufacturing (part 7), and FIG. 13C is a view corresponding to FIG. 6A during the process of manufacturing (part 7).

FIG. 14A is a view corresponding to FIG. 4A during the process of manufacturing (part 8), FIG. 14B is a view corresponding to FIG. 5A during the process of manufacturing (part 8), and FIG. 14C is a view corresponding to FIG. 6A during the process of manufacturing (part 8).

FIG. 15A is a view corresponding to FIG. 4A during the process of manufacturing (part 9), FIG. 15B is a view corresponding to FIG. 5A during the process of manufacturing (part 9), and FIG. 15C is a view corresponding to FIG. 6A during the process of manufacturing (part 9).

FIG. 16A is a view corresponding to FIG. 4A during the process of manufacturing (part 10), FIG. 16B is a view corresponding to FIG. 5A during the process of manufacturing (part 10), and FIG. 16C is a view corresponding to FIG. 6A during the process of manufacturing (part 10).

FIG. 17A is a view corresponding to FIG. 4A during the process of manufacturing (part 11), FIG. 17B is a view corresponding to FIG. 5A during the process of manufacturing (part 11), and FIG. 17C is a view corresponding to FIG. 6A during the process of manufacturing (part 11).

FIG. 18A is a view corresponding to FIG. 4A during the process of manufacturing (part 12), FIG. 18B is a view corresponding to FIG. 5A during the process of manufacturing (part 12), and FIG. 18C is a view corresponding to FIG. 6A during the process of manufacturing (part 12).

FIG. 19A is a view corresponding to FIG. 4A during the process of manufacturing (part 13), FIG. 19B is a view corresponding to FIG. 5A during the process of manufacturing (part 13), and FIG. 19C is a view corresponding to FIG. 6A during the process of manufacturing (part 13).

FIG. 20A is a view corresponding to FIG. 4A during the process of manufacturing (part 14), FIG. 20B is a view corresponding to FIG. 5A during the process of manufacturing (part 14), and FIG. 20C is a view corresponding to FIG. 6A during the process of manufacturing (part 14).

FIG. 21A is a view corresponding to FIG. 4A during the process of manufacturing (part 15), FIG. 21B is a view corresponding to FIG. 5A during the process of manufacturing (part 15), and FIG. 21C is a view corresponding to FIG. 6A during the process of manufacturing (part 15).

FIG. 22A is a view corresponding to FIG. 4A during the process of manufacturing (part 16), FIG. 22B is a view corresponding to FIG. 5A during the process of manufacturing (part 16), and FIG. 22C is a view corresponding to FIG. 6A during the process of manufacturing (part 16).

FIG. 23A is a view corresponding to FIG. 4A during the process of manufacturing (part 17), FIG. 23B is a view corresponding to FIG. 5A during the process of manufacturing (part 17), and FIG. 23C is a view corresponding to FIG. 6A during the process of manufacturing (part 17).

FIG. 24A is a view corresponding to FIG. 4B during the process of manufacturing (part 18), FIG. 24B is a view corresponding to FIG. 5B during the process of manufacturing (part 18), and FIG. 24C is a view corresponding to FIG. 6B during the process of manufacturing (part 18).

FIG. 25A is a view corresponding to FIG. 4B during the process of manufacturing (part 19), FIG. 25B is a view corresponding to FIG. 5B during the process of manufacturing (part 19), and FIG. 25C is a view corresponding to FIG. 6B during the process of manufacturing (part 19).

FIG. 26A is a view corresponding to FIG. 4B during the process of manufacturing (part 20), FIG. 26B is a view corresponding to FIG. 5B during the process of manufacturing (part 20), and FIG. 26C is a view corresponding to FIG. 6B during the process of manufacturing (part 20).

FIG. 27A is a view corresponding to FIG. 4B during the process of manufacturing (part 21), FIG. 27B is a view corresponding to FIG. 5B during the process of manufacturing (part 21), and FIG. 27C is a view corresponding to FIG. 6B during the process of manufacturing (part 21).

FIGS. 28A and 28B illustrate a second embodiment, where FIG. 28A is a view corresponding to FIG. 4A, and FIG. 28B illustrates an example of a schematic cross-sectional configuration of a capacitance element and is an example of a schematic cross-sectional view taken along a line E-E in FIG. 29.

FIG. 29 is an example of a plan view illustrating the layout pattern of the capacitance element.

FIG. 30 is a view corresponding to FIG. 28B in which contacts are formed.

FIG. 31A is a view corresponding to FIG. 28A during the process of manufacturing (part 1), and FIG. 31B is a view corresponding to FIG. 28B during the process of manufacturing (part 1).

FIG. 32A is a view corresponding to FIG. 28A during the process of manufacturing (part 2), and FIG. 32B is a view corresponding to FIG. 28B during the process of manufacturing (part 2).

FIG. 33A is a view corresponding to FIG. 28A during the process of manufacturing (part 3), and FIG. 33B is a view corresponding to FIG. 28B during the process of manufacturing (part 3).

FIG. 34A is a view corresponding to FIG. 28A during the process of manufacturing (part 4), and FIG. 34B is a view corresponding to FIG. 28B during the process of manufacturing (part 4).

FIG. 35A is a view corresponding to FIG. 28A during the process of manufacturing (part 5), and FIG. 35B is a view corresponding to FIG. 28B during the process of manufacturing (part 5).

FIG. 36A is a view corresponding to FIG. 28A during the process of manufacturing (part 6), and FIG. 36B is a view corresponding to FIG. 28B during the process of manufacturing (part 6).

FIG. 37A is a view corresponding to FIG. 28A during the process of manufacturing (part 7), and FIG. 37B is a view corresponding to FIG. 28B during the process of manufacturing (part 7).

FIG. 38A is a view corresponding to FIG. 28A during the process of manufacturing (part 8), and FIG. 38B is a view corresponding to FIG. 28B during the process of manufacturing (part 8).

FIG. 39A is a view corresponding to FIG. 28A during the process of manufacturing (part 9), and FIG. 39B is a view corresponding to FIG. 28B during the process of manufacturing (part 9).

FIG. 40A is a view corresponding to FIG. 28A during the process of manufacturing (part 10), and FIG. 40B is a view corresponding to FIG. 28B during the process of manufacturing (part 10).

FIG. 41A is a view corresponding to FIG. 28A during the process of manufacturing (part 11), and FIG. 41B is a view corresponding to FIG. 28B during the process of manufacturing (part 11).

FIG. 42A is a view corresponding to FIG. 28A during the process of manufacturing (part 12), and FIG. 42B is a view corresponding to FIG. 28B during the process of manufacturing (part 12).

FIG. 43A is a view corresponding to FIG. 28A during the process of manufacturing (part 13), and FIG. 43B is a view corresponding to FIG. 28B during the process of manufacturing (part 13).

FIG. 44A is a view corresponding to FIG. 28A during the process of manufacturing (part 14), and FIG. 44B is a view corresponding to FIG. 28B during the process of manufacturing (part 14).

FIG. 45A is a view corresponding to FIG. 28A during the process of manufacturing (part 15), and FIG. 45B is a view corresponding to FIG. 28B during the process of manufacturing (part 15).

FIG. 46A is a view corresponding to FIG. 28A during the process of manufacturing (part 16), and FIG. 46B is a view corresponding to FIG. 28B during the process of manufacturing (part 16).

FIG. 47A is a view corresponding to FIG. 28A during the process of manufacturing (part 17), and FIG. 47B is a view corresponding to FIG. 28B during the process of manufacturing (part 17).

FIG. 48A is a view corresponding to FIG. 28A during the process of manufacturing (part 18), and FIG. 48B is a view corresponding to FIG. 28B during the process of manufacturing (part 18).

FIG. 49A is a view corresponding to FIG. 28A during the process of manufacturing (part 19), and FIG. 49B is a view corresponding to FIG. 28B during the process of manufacturing (part 19).

FIG. 50A is a view corresponding to FIG. 28A during the process of manufacturing (part 20), and FIG. 50B is a view corresponding to FIG. 28B during the process of manufacturing (part 20).

FIG. 51 illustrates a schematic cross-sectional configuration of a resistance element according to a third embodiment, and is an example of a cross-sectional view taken along a line F-F in FIG. 52.

FIG. 52 is an example of a plan view illustrating a layout pattern of the resistance element.

FIGS. 53A to 53C illustrate a fourth embodiment, where FIG. 53A is a view corresponding to FIG. 4A, and FIG. 53B is a view corresponding to FIG. 4B, and FIG. 53C is a view corresponding to FIG. 2.

FIG. 54 is a view corresponding to FIG. 53A during the process of manufacturing (part 1).

FIG. 55 is a view corresponding to FIG. 53A during the process of manufacturing (part 2).

FIG. 56 is a view corresponding to FIG. 53A during the process of manufacturing (part 3).

FIG. 57 is a view corresponding to FIG. 53A during the process of manufacturing (part 4).

FIG. 58 is a view corresponding to FIG. 53A during the process of manufacturing (part 5).

FIG. 59 is a view corresponding to FIG. 53A during the process of manufacturing (part 6).

FIG. 60 is a view corresponding to FIG. 53A during the process of manufacturing (part 7).

FIG. 61 is a view corresponding to FIG. 53A during the process of manufacturing (part 8).

FIG. 62 is a view corresponding to FIG. 53A during the process of manufacturing (part 9).

FIGS. 63A and 63B are views illustrating a fifth embodiment and correspond to FIG. 53A and FIG. 53B, respectively.

FIGS. 64A and 64B are views illustrating a sixth embodiment and correspond to FIG. 53A and FIG. 53B, respectively.

### DETAILED DESCRIPTION

An object of an exemplary embodiment is to miniaturize a semiconductor device which includes an SOI structure.

In general, according to one embodiment, a semiconductor device includes a first insulating film that is formed on a memory cell region of the semiconductor substrate, a first polysilicon layer that is formed on the first insulating film, and memory cell transistors that are formed on the first polysilicon layer with a gate insulating film interposed therebetween. Each of the memory cell transistors has a first laminated structure including a charge storage layer, an inter-electrode insulating film and a control gate electrode. The semiconductor device further includes a second laminated structure that is formed on a peripheral circuit region of the semiconductor substrate and includes a second insulating film, a second polysilicon layer, a third insulating film, a third polysilicon layer, a fourth insulating film, and a first electrode. The third polysilicon layer, the fourth insulating film, and the first electrode are arranged to form a first capacitance element. In addition, the fourth insulating film and the inter-electrode insulating film are formed from the same material, and the first electrode and the control gate electrode are formed from the same material.

Hereinafter, a plurality of embodiments will be described with reference to the accompanying drawings. Also, in each embodiment, the same reference numerals are assigned to components which are almost the same, and the descriptions thereof are not repeated. However, the drawings are schematic, and the relationship between thickness and planar dimensions and the thickness ratio of each layer may differ from actual implementations.

### First Embodiment

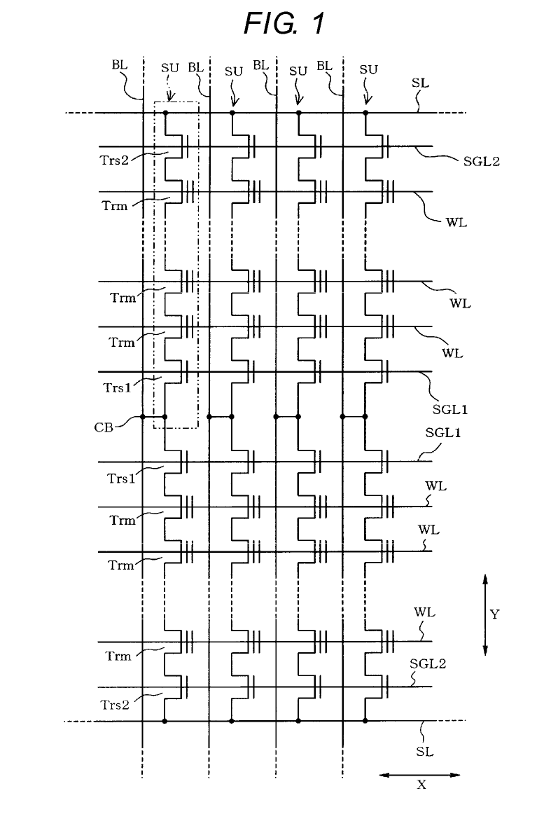

First, FIG. 1 is an example of an equivalent circuit diagram illustrating a part of a memory cell array which is formed in a memory cell region of a NAND-type flash memory device according to a first embodiment. As shown in FIG. 1, the memory cell array of the NAND-type flash memory device is configured in such a way that NAND cell units SU, each of which includes two selection gate transistors Trs1 and Trs2 and a plurality of (for example, 32) memory cell transistors Trm connected in series between the selection gate transistors Trs1 and Trs2, are formed in a matrix. In each NAND cell unit SU, the plurality of memory cell transistors Trm are formed such that adjacent memory cell transistors share source and drain regions.

Memory cell transistors Trm which are arranged in the X direction (corresponding to the word line direction and the gate width direction) in FIG. 1 are commonly connected by a word line WL. In addition, selection gate transistors Trs1 which are arranged in the X direction in FIG. 1 are commonly connected by a selection gate line SGL1, and selection gate transistors Trs2 are commonly connected by a selection gate line SGL2. The drain regions of the selection gate transistors Trs1 are connected to bit-line contacts CB. The bit-line contacts CB are connected to bit lines BL which extend in the Y direction (corresponding to the gate length direction and the bit line direction) that is perpendicular to the X direction in FIG. 1. In addition, the selection gate transistors Trs2 are connected to a source line SL which extends in the X direction in FIG. 1 via the source regions.

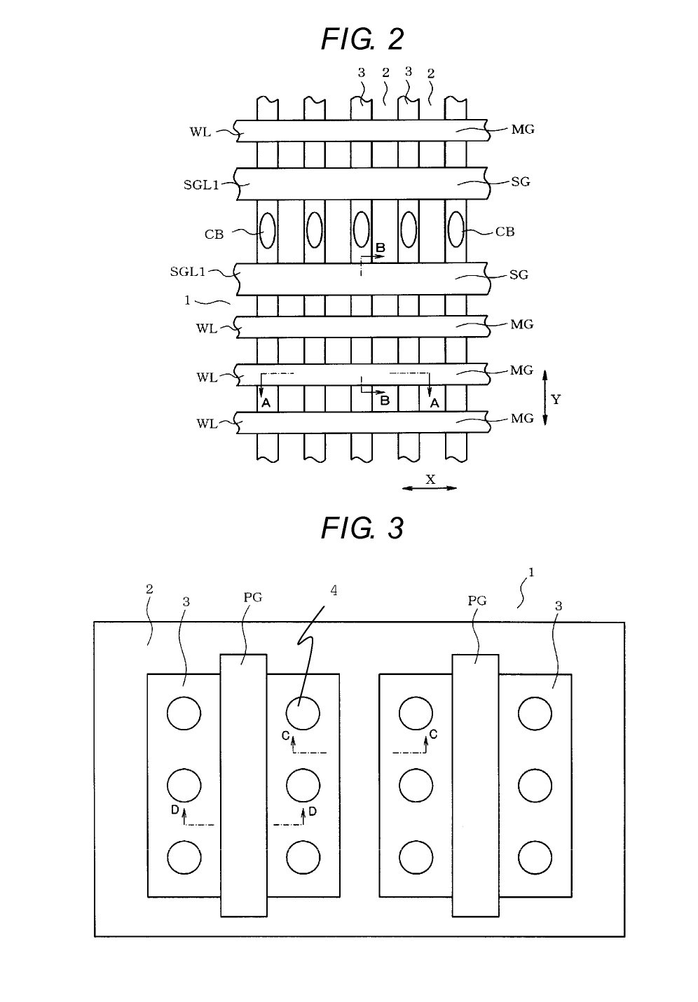

FIG. 2 is an example of a plan view illustrating the layout pattern of a part of the memory cell region. On a silicon substrate 1 which functions as a semiconductor substrate, Shallow Trench Isolations (STI) 2, which function as element isolation regions extending along the Y direction in FIG. 2, are formed in the X direction in FIG. 2 at predetermined intervals. Therefore, element regions 3, which extend along the Y direction in FIG. 2, are separately formed in the X direction in FIG. 2. Word lines WL for the memory cell transistors are formed to extend along the direction (in the X direction in FIG. 2), which is perpendicular to the element regions 3, at predetermined intervals in the Y direction in FIG. 2.

In addition, a pair of selection gate lines SGL1 of selection gate transistors is formed to extend along the X direction in FIG. 2. A bit-line contact CB is formed in each of the element regions 3 between the pair of selection gate lines SGL1. The gate electrodes MG of the memory cell transistors are formed on the element regions 3 which cross the word line WL, and the gate electrodes SG of the selection gate transistors are formed on the element regions 3 which cross the selection gate line SGL1.

FIG. 3 is an example of a plan view illustrating the layout pattern of a part of a peripheral circuit region. An STI 2 is formed surrounding the element regions 3 on the silicon substrate 1. A gate electrode PG is formed to traverse each element region 3 on the upper portion of each element region 3 in the vertical direction in FIG. 3. Contacts 4 are formed on both sides of the gate electrode PG in the element region 3.

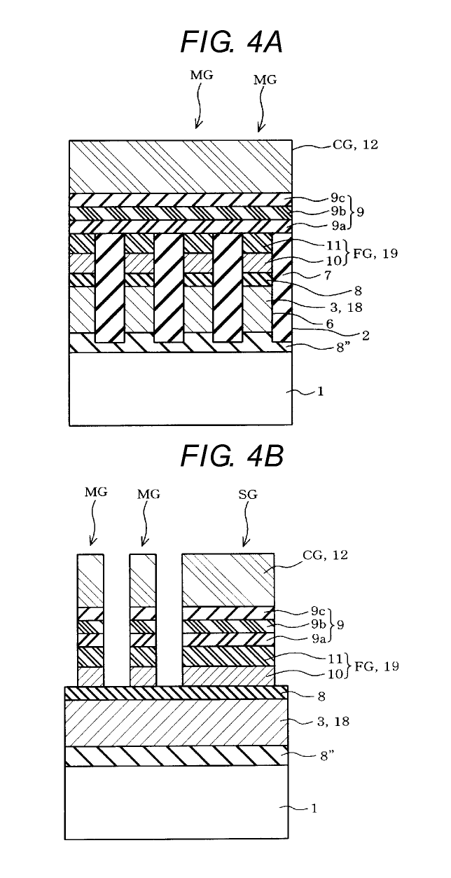

Next, the structure of the gate electrode in the memory cell region according to the embodiment will be described with reference to FIGS. 4A and 4B. FIG. 4A is a view schematically showing a cross section taken along a line A-A (the word line direction and the X direction) in FIG. 2, and FIG. 4B is a view schematically showing a cross section taken along a line B-B (the bit line direction and the Y direction) in FIG. 2.

As shown in FIGS. 4A and 4B, an insulating film 8″ (a first insulating film) is formed on the upper portion of the silicon substrate 1, and the element regions 3 are separately formed above the insulating film 8″ in the X direction via element isolation grooves 6. For example, a polysilicon film 18 (a first polysilicon layer) is used as the element region 3. An element isolation insulating film 7 is formed in each of the element isolation grooves 6 and constitutes the element isolation region (STI) 2.

The memory cell transistor Trm includes the gate insulating film 8 which is formed in the element region 3, the gate electrode MG which is provided above the gate insulating film 8, and a diffused layer (not shown in the drawing) which is formed in the element region 3. The gate electrode MG includes a floating gate electrode FG which functions as a charge storage layer, an inter-electrode insulating film 9 which is formed on the floating gate electrode FG, and a control gate electrode CG which is formed on the inter-electrode insulating film 9. The diffused layer is positioned and formed on the sides of the gate electrode MG of the memory cell transistor on the surface layer of the element region 3, and constitutes the source and drain regions of the memory cell transistor.

The gate insulating film 8 is a film which is called a tunnel insulating film and, for example, a silicon oxide film is used. For example, a film in which a polysilicon layer (a conductive layer) 10 and a trapped film 11 are laminated is used as the floating gate electrode FG. A silicon nitride film or a film which includes a rare-earth oxide is used as the trapped film 11. The inter-electrode insulating film 9 functions as an inter-poly insulating film, an inter-conductive layer insulating film, and an inter-electrode insulating film. It is preferable to use a single layer film or a laminated film of, for example, the silicon oxide film, the silicon nitride film, and the film which includes a rare-earth oxide as the inter-electrode insulating film 9. In the embodiment, a laminated film in which a silicon oxide film 9a, a silicon nitride film 9b, and a hafnium oxide film 9c are laminated is used as the inter-electrode insulating film 9.

The control gate electrode CG includes a conductive layer 12 which functions as the word line WL for the memory cell transistors. For example, a tungsten (W) layer is used as the conductive layer 12. Also, a laminated layer of the polysilicon layer and the tungsten (W) layer may be used as the conductive layer 12. In addition, a film including a laminated structure having the polysilicon layer and a silicide layer silicided by any one of metals, such as tungsten (W), cobalt (Co), and nickel (Ni), formed on the polysilicon layer, may be used. Further, the entire conductive layer 12 may be configured with the silicide layer (that is, the silicide layer alone).

In addition, as shown in FIG. 4B, the gate electrodes MG of the memory cell transistors are provided in parallel in the Y direction, and are electrically separated from each other. An inter-memory cell insulating film (not shown in the drawing) is formed between the gate electrodes MG. For example, a silicon oxide film using a Tetraethyl Orthosilicate (TEOS) or a low-dielectric insulating film is used as the inter-memory cell insulating film. A liner insulating film (not shown in the drawing) which includes, for example, a silicon nitride film is formed above the inter-memory cell insulating film and the control gate electrode CG, and an inter-layer insulating film (not shown in the drawing) which includes, for example, a silicon oxide film, is formed on the liner insulating film.

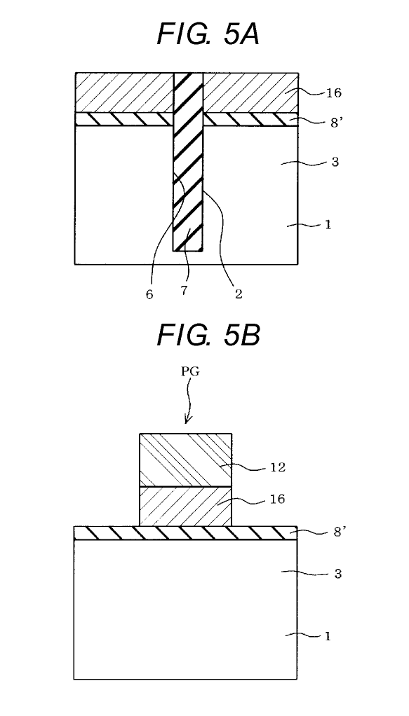

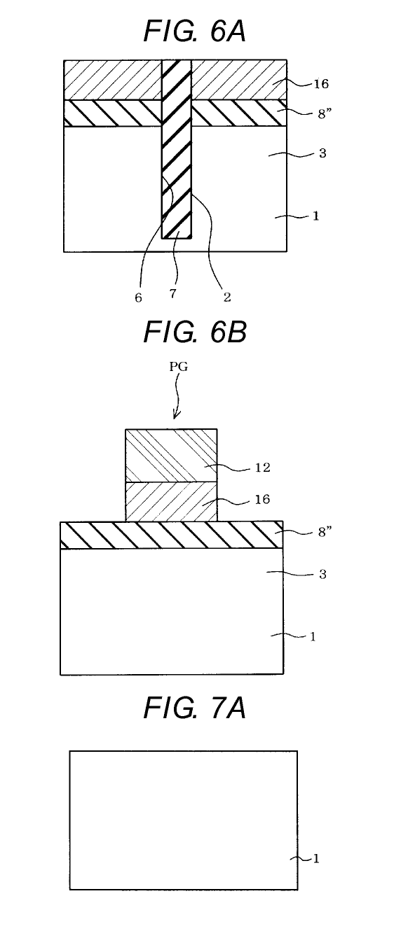

In addition, a structure of the gate electrode in the peripheral circuit region according to the embodiment will be described with reference to FIGS. 5A to 6B. FIGS. 5A and 5B show the structure of the gate electrode of a peripheral transistor in a low voltage system, and FIGS. 6A and 6B show the structure of the gate electrode of the peripheral transistor in a high voltage system. FIGS. 5A and 6A are views schematically illustrating the cross sections taken along a line C-C in FIG. 3 and FIGS. 5B and 6B are views schematically illustrating the cross sections taken along a line D-D in FIG. 3.

As shown in FIGS. 5A and 5B, the structure of the gate electrode of the peripheral transistor for the low voltage operation includes a gate insulating film 8′ which is formed above the element region 3 of the silicon substrate 1, a gate electrode PG which is provided above the gate insulating film 8′, and a diffused layer (not shown in the drawing) which is formed in the element region 3. The gate electrode PG includes a polysilicon layer 16 which is formed on the gate insulating film 8′ and a tungsten layer 12 which is formed on the polysilicon layer 16. Also, the STI 2 includes the element isolation groove 6 and an element isolation insulating film 7 which is buried in the element isolation groove 6.

In addition, as shown in FIGS. 6A and 6B, the structure of the gate electrode of the peripheral transistor for the high voltage operation is almost the same as the structure of the gate electrode of the peripheral transistor for the low voltage operation, and the difference is that the film thickness of the gate insulating film 8″ is thicker than the film thickness of the gate insulating film 8′ of the peripheral transistor in the low voltage system.

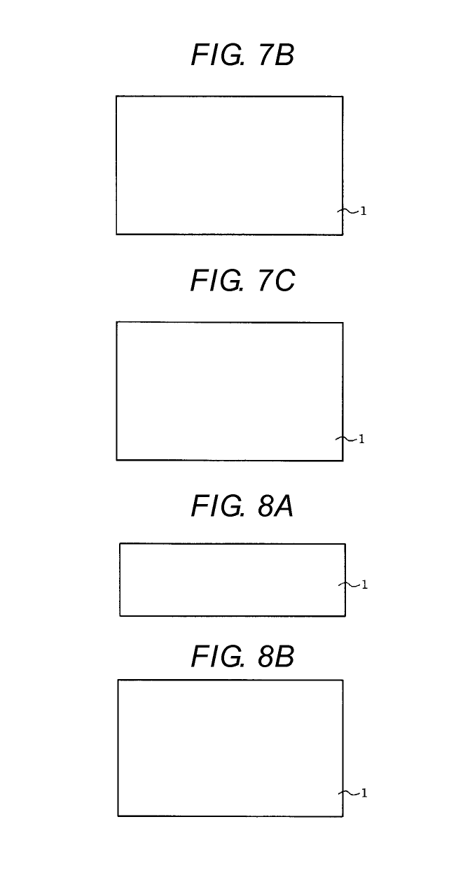

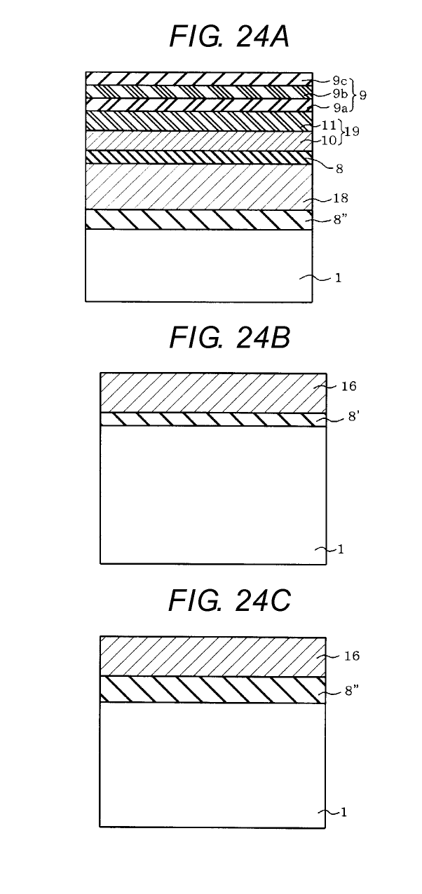

Meanwhile, a manufacturing method according to the embodiment applied to the NAND-type flash memory device including the above-described components will be described with reference to FIGS. 7A to 27C. Also, FIGS. 7A to 23A are views schematically illustrating cross sections taken along a line A-A in FIG. 2 and are views illustrating the cross sections which correspond to the structure in FIG. 4A. FIGS. 7B to 23B are views schematically illustrating cross sections taken along a line C-C in FIG. 3 and are views illustrating the cross sections which correspond to the structure in FIG. 5A. FIGS. 7C to 23C are views schematically illustrating cross sections taken along the line C-C in FIG. 3 and are views illustrating the cross sections which correspond to the structure in FIG. 6A. In addition, FIGS. 24A to 27A are views schematically illustrating cross sections taken along a line B-B in FIG. 2 and are views illustrating the cross sections which correspond to the structure in FIG. 4B. FIGS. 24B to 27B are views schematically illustrating cross sections taken along a line D-D in FIG. 3 and are views illustrating the cross sections which correspond to the structure in FIG. 5B. FIGS. 24C to 27C are views schematically illustrating the cross sections taken along the line D-D in FIG. 3 and are views illustrating the cross sections which correspond to the structure in FIG. 6B.

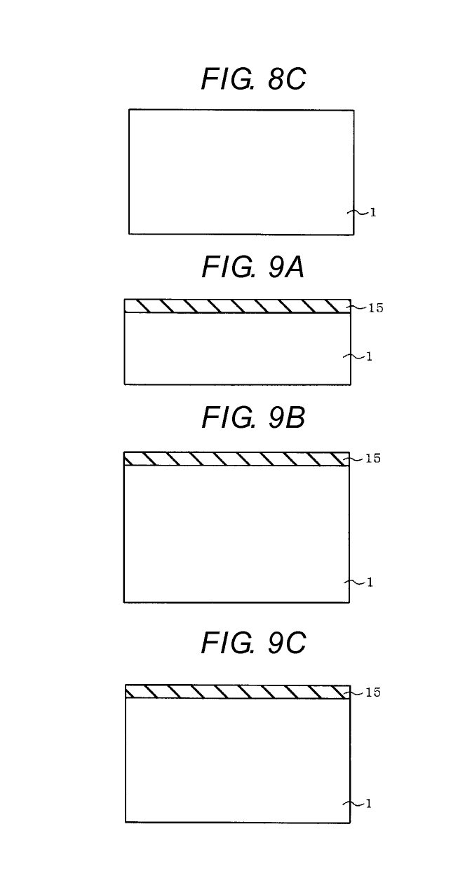

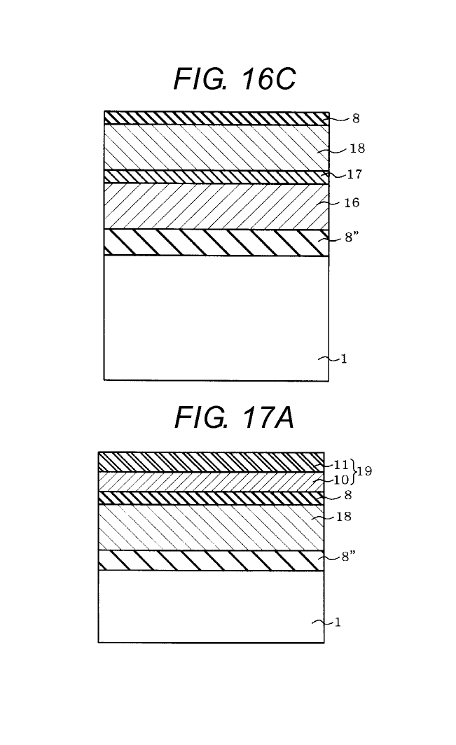

First, after a photoresist mask in which the memory cell region is exposed, is formed using photolithography on the silicon substrate 1 shown in FIGS. 7A to 7C, the memory cell regions of the silicon substrate 1 are etched, the photoresist mask in which the high voltage operation region of the peripheral circuit region is exposed, is formed using the photolithography, and the high voltage operation region of the peripheral circuit region on the silicon substrate 1 is etched. Therefore, as shown in FIGS. 8A to 8C, the height of the memory cell region of the silicon substrate 1, the height of the low voltage operation region of the peripheral circuit region, and the height of the high voltage operation region of the peripheral circuit region differ from each other. At this time, the amount of etching is adjusted such that the height of the upper surface of the gate insulating film 8 in the memory cell region, the height of the upper surface of the gate insulating film 8′ in the low voltage operation region, and the height of the upper surface of the gate insulating film 8″ in the high voltage operation region are almost the same as shown in FIGS. 16A to 16C.

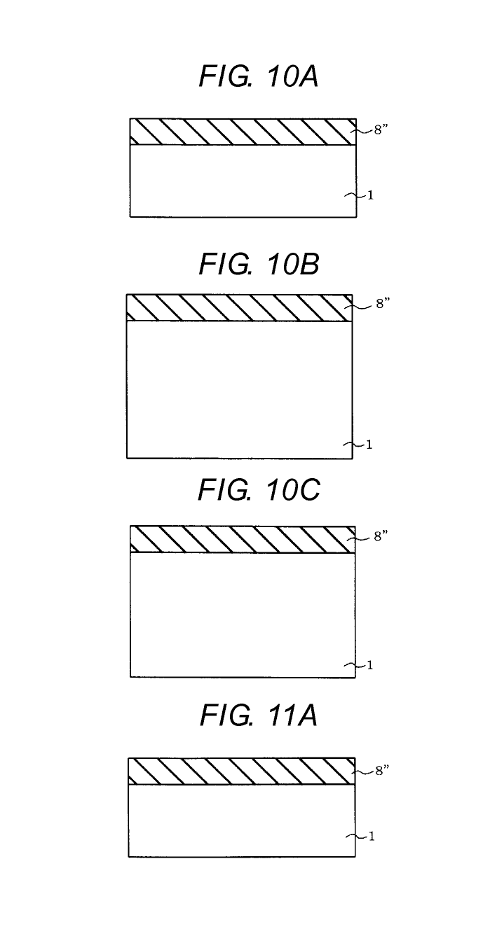

Subsequently, as shown in FIGS. 9A to 9C, the silicon oxide film 15 is formed on the upper surface of the silicon substrate 1 as a sacrificial layer. After this process is performed, it is possible to appropriately introduce dopants in order to form a well. Subsequently, the silicon oxide film 15 is removed, and the gate insulating film 8″, which is an oxide film to be buried into the memory cell region and which is the gate insulating film 8″ for the peripheral transistors in the high voltage operation, is formed, as shown in FIGS. 10A to 10C. It is preferable to use a thermally-oxidized film as the gate insulating film 8″ in consideration of reliability. Also, the gate insulating film 8″ may be formed by a deposition process. In addition, the film thickness of the gate insulating film 8″ is set to, for example, 30 to 40 nm.

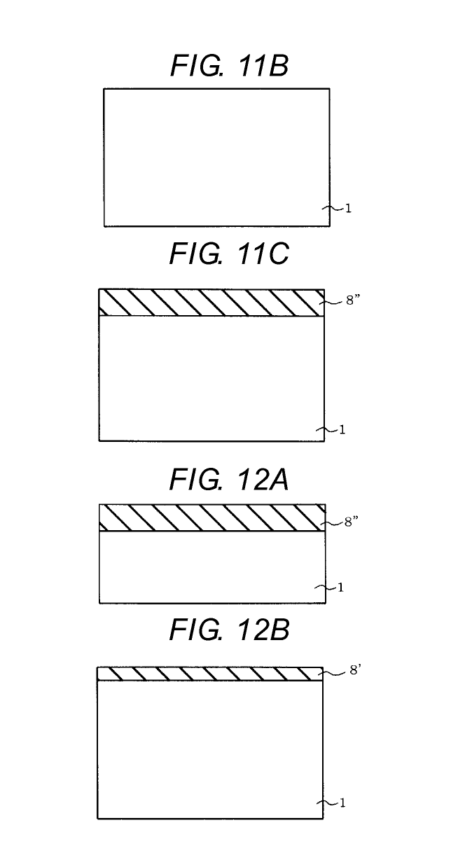

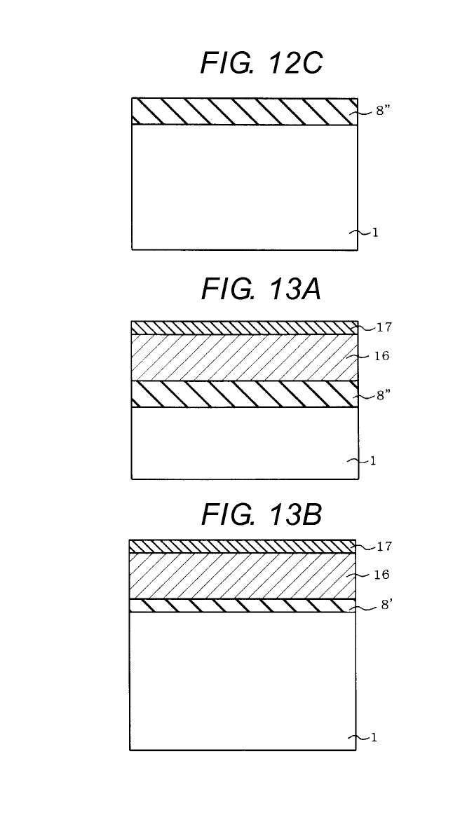

Subsequently, after the photoresist mask in which the low voltage operation region of the peripheral circuit region is exposed, is formed using photolithography, the gate insulating film 8″ in the low voltage operation region is etched and detached using, for example, dilute hydrofluoric acid-based WET etching. Therefore, configurations shown in FIGS. 11A to 11C are obtained. Subsequently, the gate oxide film 8′ in the low voltage operation is formed in the low voltage operation region on the silicon substrate 1 using thermal oxidation as shown in FIGS. 12A to 12C.

Thereafter, as shown in FIGS. 13A to 13C, a polysilicon layer 16 which is the gate electrode in the peripheral circuit region is formed above the gate insulating film 8′ or 8″, and a silicon nitride film 17 is formed on the polysilicon layer 16. In this case, it is preferable to form the polysilicon layer 16 to be polysilicided in such a way as to, for example, form an amorphous silicon layer and then anneal the amorphous silicon layer. In addition, the polysilicon layer may be directly formed. Also, it is possible to implant boron, arsenic, or phosphorus into the polysilicon layer 16 to an extent such that the gate electrode is not depleted (for example, 1×10²⁰ cm⁻³ or greater).

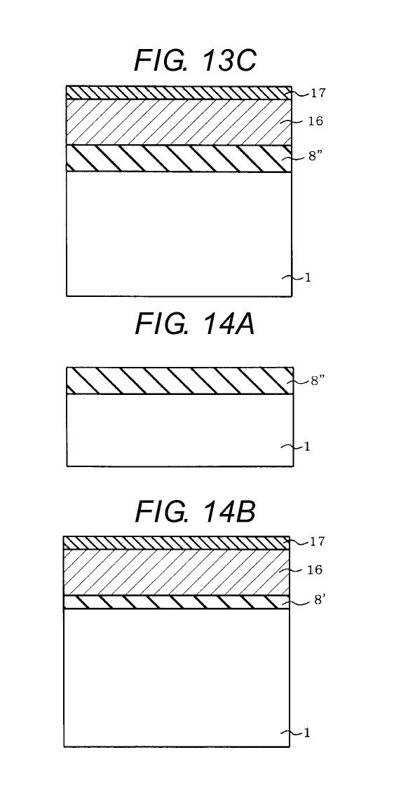

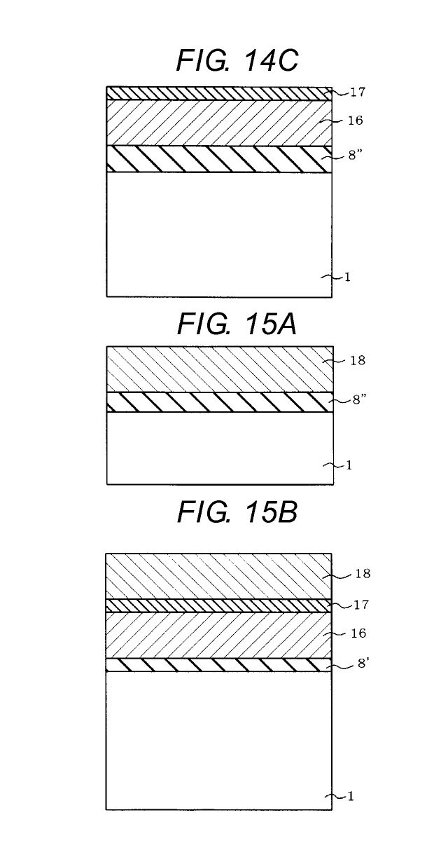

Subsequently, as shown in FIGS. 14A to 14C, after the photoresist mask in which the memory cell region is exposed, is formed using photolithography, the silicon nitride film 17 and the polysilicon layer 16 in the memory cell region are removed using, for example, Reactive Ion Etching (RIE). Thereafter, the upper portion of the oxide film 8″ which is buried in the memory cell region is removed using, for example, WET etching to remove the upper portion of the oxide film having the RIE damage. At this time, the reason why the silicon nitride film 17 is used on the polysilicon layer 16 in the peripheral circuit region instead of the silicon oxide film will be described. If the silicon oxide film is used instead of the silicon nitride film 17, the WET etching (for example, a hydrofluoric acid treatment) for removing the upper portion of the oxide film 8″, the inter-polysilicon insulating film of a peripheral circuit portion in a capacitance element scheduled region is eliminated by performing oxide film etching. Thus it is not possible to form a capacitance element shown in FIG. 30 which will be described later. However, when the WET etching is not performed to remove the upper portion of the oxide film 8″ with RIE damage, the silicon oxide film may be used instead of the silicon nitride film 17.

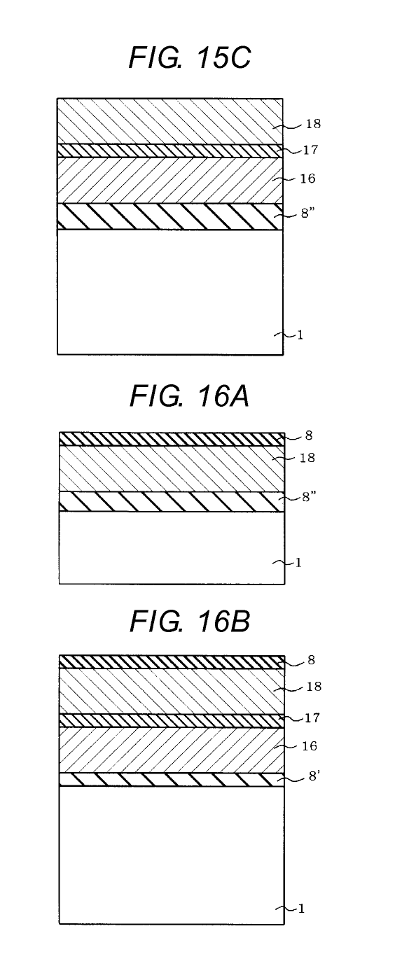

Thereafter, as shown in FIGS. 15A to 15C, a polysilicon layer 18 which is the channel region of the memory cell region is formed. It is preferable to form the polysilicon layer 18 to be polysilicided in such a way as to, for example, form an amorphous silicon layer and then anneal the amorphous silicon layer. In addition, the polysilicon layer may be directly formed. Thereafter, in order to prevent current drive force from being lowered, the concentration of the dopants of the polysilicon layer 18 is set to be lower than the concentration of the dopants of the polysilicon layer 16 which is used as the gate electrode in the peripheral circuit region, and the grain size of the polysilicon of the polysilicon layer 18 is set to be greater than the grain size of the polysilicon of the polysilicon layer 16 which is used as the gate electrode in the peripheral circuit region. Further, in order to reduce an aspect ratio when the element isolation groove in the memory cell region is processed and in order to improve the cut-off properties of the memory cell transistor, it is preferable to set the film thickness of the polysilicon layer 18 to, for example, 100 nm or less.

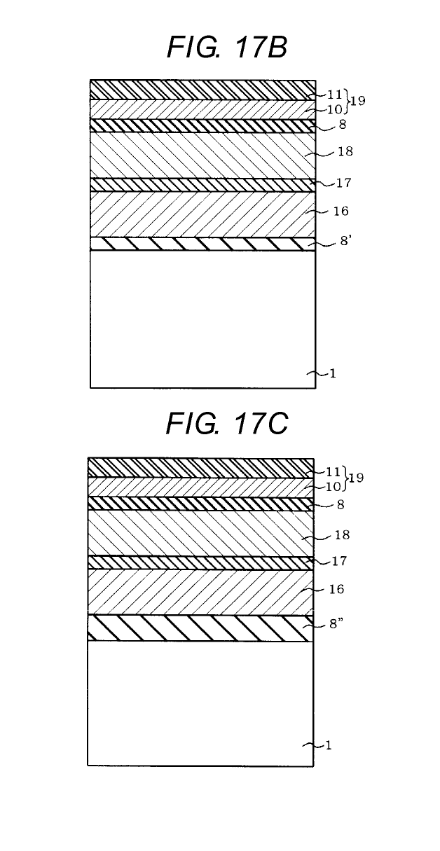

Subsequently, as shown in FIGS. 16A to 16C, the gate insulating film 8 is formed as a tunnel insulating film above the polysilicon layer 18. For example, the silicon oxide film or a laminated film which includes a silicon nitride film, a polysilicon film and a rare-earth oxide film may be used as the gate insulating film 8. Subsequently, as shown in FIGS. 17A to 17C, the charge storage layer (the floating gate electrode FG) 19 is formed on the gate insulating film 8. The polysilicon layer 10 with a film thickness of, for example, 6 to 8 nm and the trapped film 11 with a film thickness of, for example, 6 to 7 nm are laminated and formed as the charge storage layer 19. Instead of the polysilicon layer 10, a metallic layer including Ti, Ta, Mo or W or a laminated film, in which the polysilicon layer and the metallic layer including Ti, Ta, Mo, or W are laminated, may be used as a conductive layer. It is preferable to use a silicon nitride film or a hafnium oxide film as the trapped film 11.

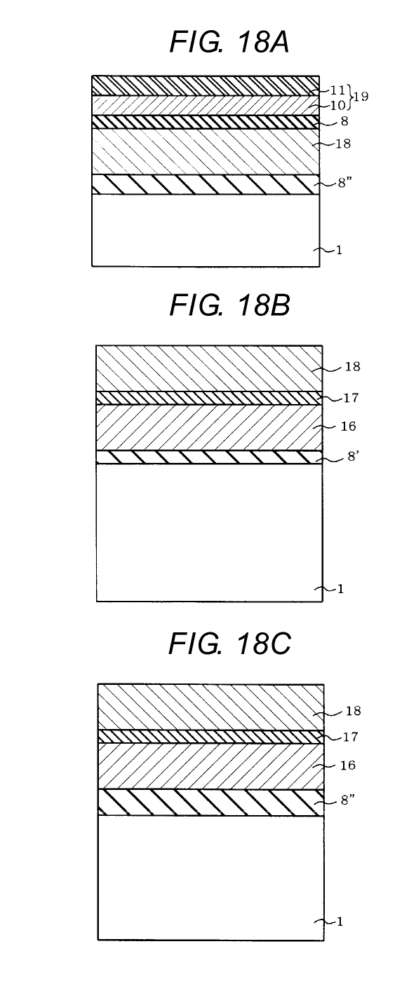

Thereafter, as shown in FIGS. 18A to 18C, after the photoresist mask in which regions excepting the memory cell region are exposed, is formed using photolithography, the charge storage layer 19 and the gate insulating film 8 in the regions excepting the memory cell region are etched and removed using, for example, the RIE.

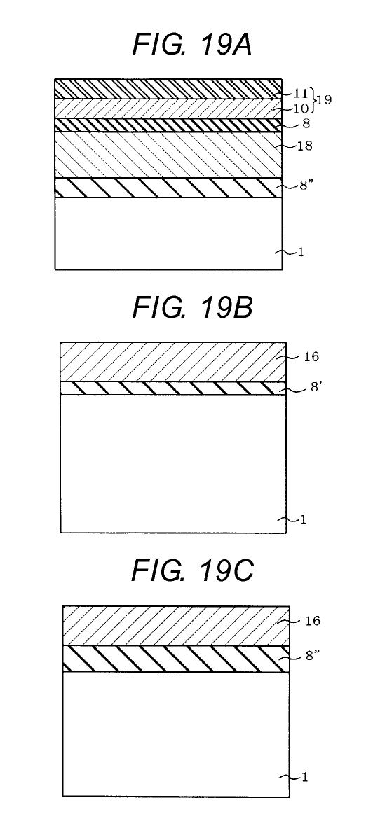

Subsequently, as shown in FIGS. 19A to 19C, after the photoresist mask in which the low voltage operation region and the high voltage operation region of the peripheral circuit region are exposed, is formed using photolithography, it is possible to remove the polysilicon layer 18 in the low voltage region and the high voltage region in such a way that the silicon nitride film 17 is used as a stopper using, for example, the RIE method. Thereafter, the silicon nitride film 17 is etched and removed. Meanwhile, it is possible to etch the polysilicon layer 18 and the silicon nitride film 17 at the same time. Thereafter, the photoresist mask is removed. Therefore, all the regions are configured to include almost the same heights.

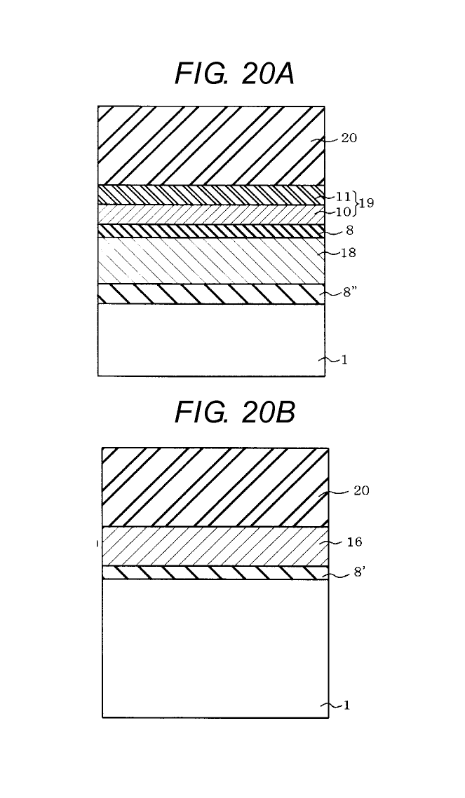

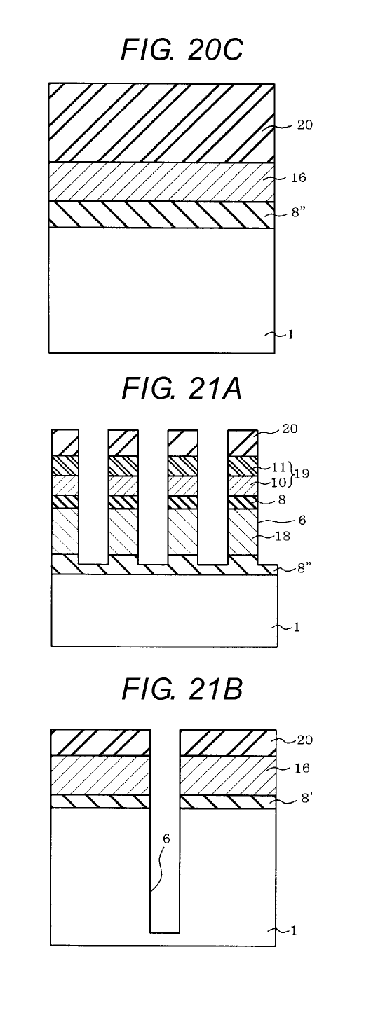

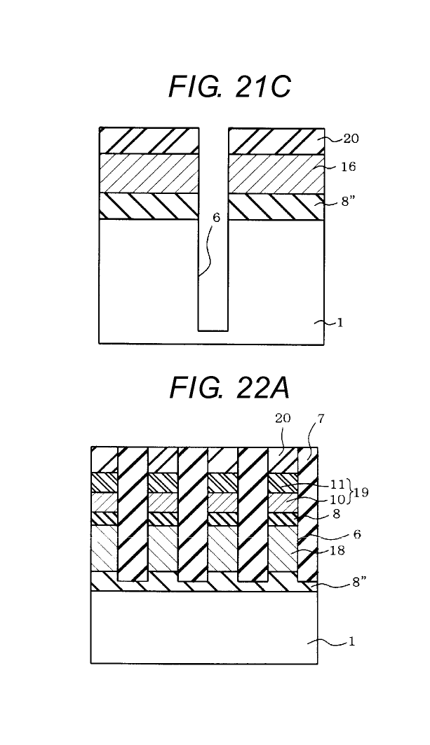

Thereafter, as shown in FIGS. 20A to 20C, a silicon nitride film 20 is formed as a mask material in order to process the element isolation groove 6. Subsequently, as shown in FIGS. 21A to 21C, after the photoresist mask having a space pattern is formed by using photolithography in order to process the element isolation groove 6. Then, etching is performed using, for example, the RIE, and thus the element isolation groove 6 is formed. Also, when the element isolation groove 6 is processed, a sidewall transfer process may be used.

Then, the silicon nitride film 20, the charge storage layer 19, the gate insulating film 8 and the polysilicon layer 18 are subsequently etched in the memory cell region, and the etching stops in the buried insulating film 8″. Even in a configuration in which the amount of etching is comparatively small as described above, the buried insulating film 8″ is present. Therefore, if the element isolation insulating film 7 is buried in the element isolation groove 6, it is possible to obtain sufficient insulation properties for the element isolation. Further, according to the embodiment, even in a configuration in which the width of an opening of the element isolation groove 6 in the memory cell region is miniaturized, it is possible to reduce the aspect ratio while the amount of the etching process is small, and thus it is possible to prevent the collapse or twisting of a pattern.

On the other hand, as shown in FIGS. 21B and 21C, in the peripheral circuit region, the depth of the element isolation groove 6 is deeper than the lower surface of the insulating film 8′ or 8″ for element isolation, and thus it is possible to obtain sufficient insulation properties for the element isolation.

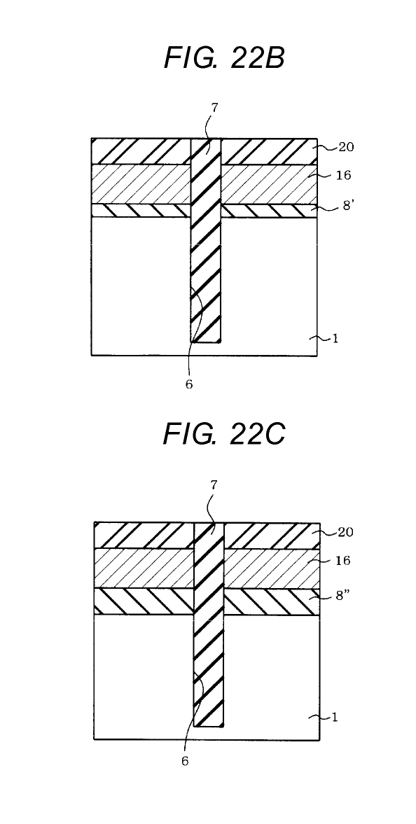

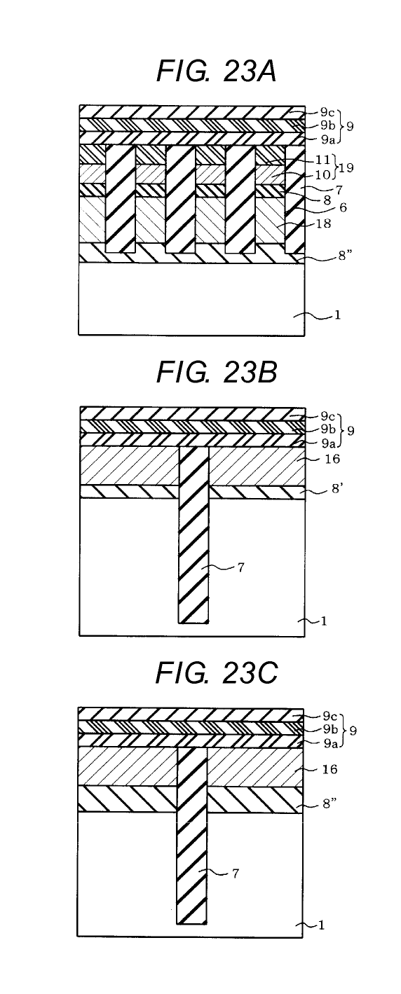

Subsequently, the element isolation insulating film 7 is buried in the element isolation groove 6, and then planarization is performed in such a way as to use the silicon nitride film 20 as a stopper using Chemical Mechanical Polishing (CMP), thereby acquiring configurations shown in FIGS. 22A to 22C. Subsequently, the silicon nitride film 20 is etched and removed using chemicals. Further, the upper portion of the element isolation insulating film 7 is etched back, and thus the height of the upper surface of the element isolation insulating film 7 is almost the same as the height of the upper surface of the trapped film 11 (refer to FIGS. 23A to 23C).

Thereafter, as shown in FIGS. 23A to 23C, the inter-electrode insulating film (block insulating film and the inter-poly insulating film) 9 is formed on the element isolation insulating film 7 and the trapped film 11. In the embodiment, for example, a three-layered laminated film (the silicon oxide film 9a, the silicon nitride film 9b, and the rare-earth oxide film 9c) is used as the inter-electrode insulating film 9.

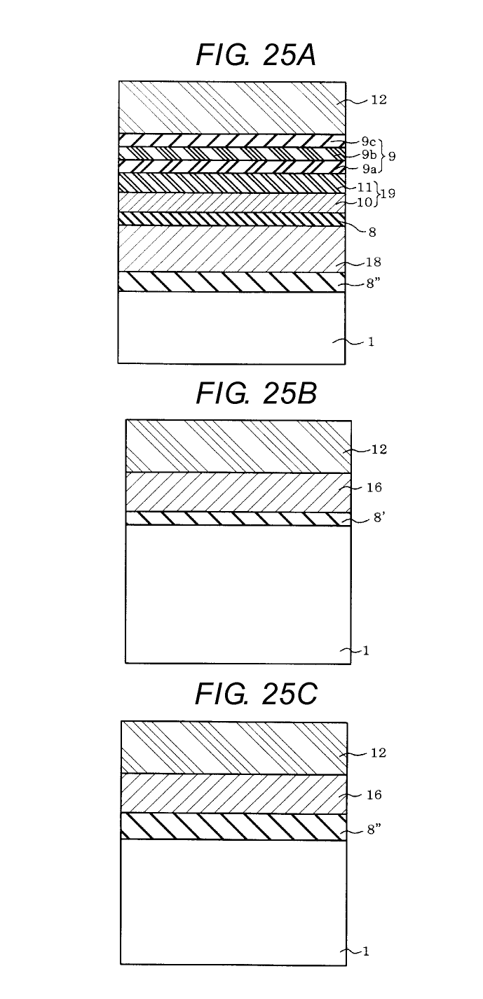

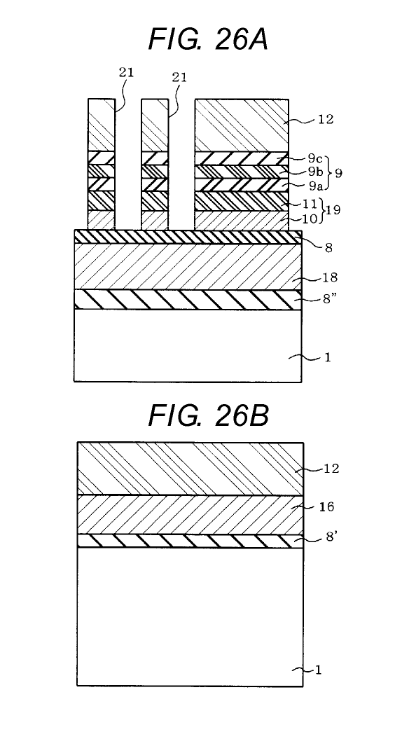

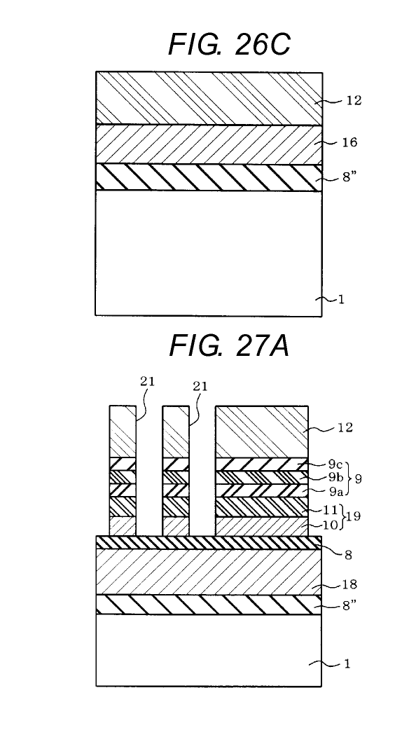

Subsequently, after the photoresist mask in which the peripheral circuit region is exposed by using photolithography, the inter-electrode insulating film 9 of the peripheral circuit region is etched and removed using, for example, the RIE method. Therefore, configurations shown in FIGS. 24A to 24C are obtained. Also, FIG. 24A (FIG. 25A and FIG. 26A) is a view schematically illustrating a cross section taken along the line B-B in FIG. 2. FIG. 24B (FIG. 25B and FIG. 26B) is a view schematically illustrating a cross section taken along the line D-D in FIG. 3. FIG. 24C (FIG. 25C and FIG. 26C) is a view schematically illustrating a cross section taken along the line D-D in FIG. 3.

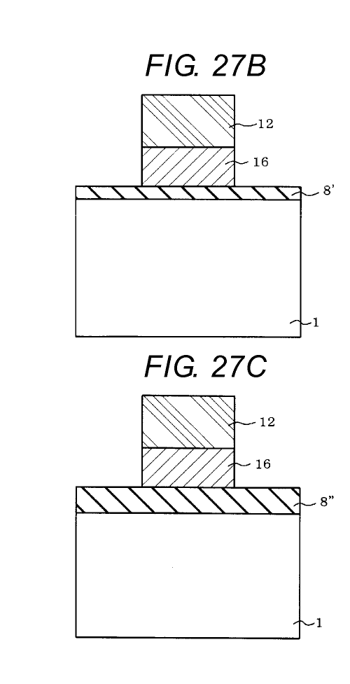

Subsequently, as shown in FIGS. 25A to 25C, the conductive layer 12 which functions as the word line WL for the memory cell transistors is formed on the inter-electrode insulating film 9 and the polysilicon layer 16. For example, a tungsten (W) layer 12 is used as the conductive layer 12. Thereafter, configurations shown in FIGS. 26A to 26C are obtained by performing the gate process in the memory cell region and forming an electrode separation groove 21. Subsequently, configurations shown in FIGS. 27A to 27C are obtained by performing the gate process in the peripheral circuit region. Thereafter, the NAND-type flash memory device is manufactured by performing the diffused layer forming process, the inter-layer insulating film forming process, the contact forming process, and the wiring forming process, respectively.

Also, the configuration of the memory cell transistors in the memory cell region according to the embodiment has the element region 3 formed on the polysilicon layer 18.

According to the embodiment including such a configuration, a configuration is made such that the element region 3 (polysilicon layer 18) is formed on the gate insulating film 8″ which functions as the buried insulating film and that the gate electrode MG is formed above the element region 3 via the gate insulating film 8, and the element isolation groove 6 is shallow. Therefore, even in a configuration in which an active region including a fine width is formed to achieve high integration, it is possible to increase mechanical strength, and it is possible to prevent the collapse or twist of a pattern. In addition, according to the embodiment, in the NAND-type flash memory device including the SOI structure in which the polysilicon layer 18 is used as the element region 3, it is possible to reduce the generation of unevenness after the gate electrode (GC) process is performed.

### Second Embodiment

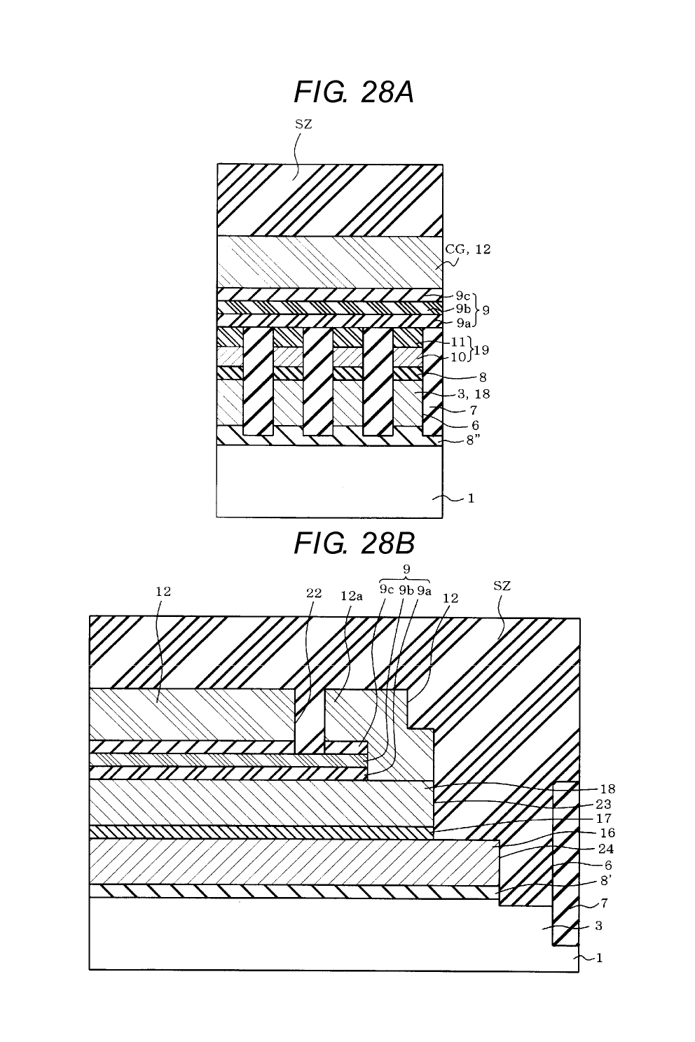

FIGS. 28A to 50 are views illustrating a second embodiment. Also, the same reference numerals are assigned to components which are the same in the first embodiment. In a process of forming the memory cell transistors (components which are the same in the first embodiment) in the memory cell region in the second embodiment, capacitance elements are formed in the peripheral circuit region at the same time. FIG. 28B shows an example of the schematic cross-section of the capacitance elements. Also, FIG. 28A shows an example of the schematic cross-section of the memory cell transistor (including the same configuration as in the first embodiment (refer to FIG. 4A)).

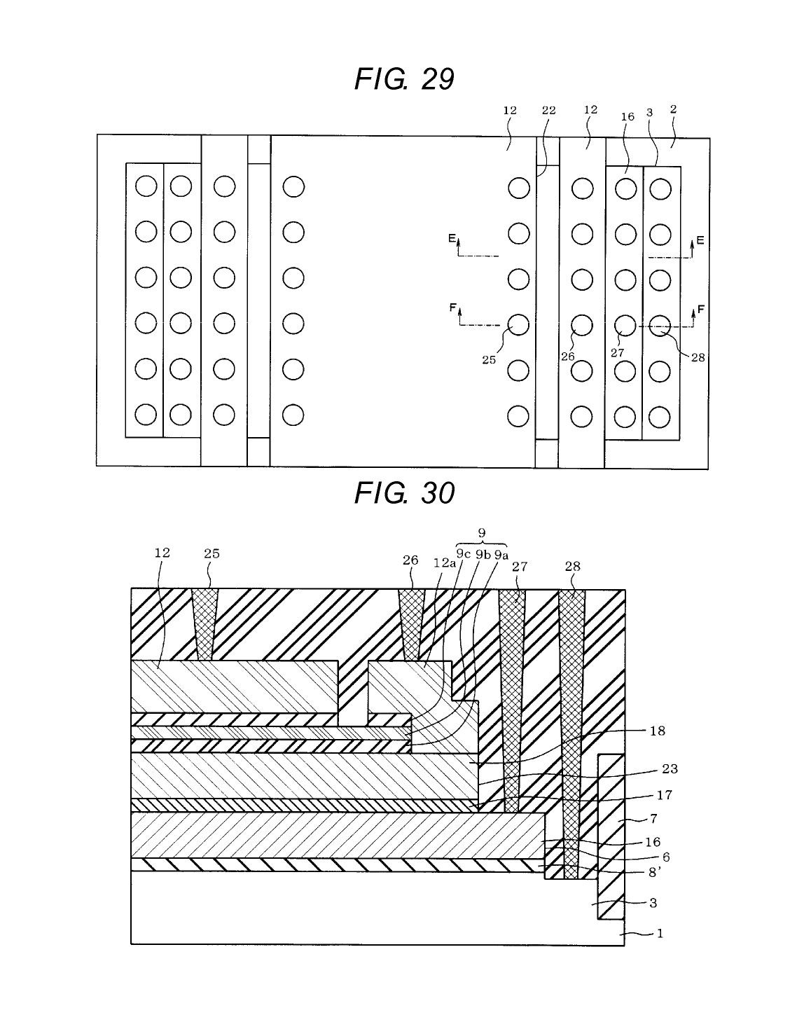

In addition, FIG. 29 is an example of a plan view illustrating the layout pattern of the capacitance elements. Also, FIG. 28B is a cross-sectional view taken along a line E-E in FIG. 29, and FIG. 30 is a cross-sectional view taken along a line F-F in FIG. 29. As shown in FIGS. 28B and 29, an STI 2 is formed on the silicon substrate 1 to enclose an element region 3. Here, as shown in FIGS. 28A and 28B, the STI 2 is configured such that an element isolation insulating film 7 is formed in an element isolation groove 6 which reaches the silicon substrate 1. A gate insulating film 8′ (second insulating film), a polysilicon layer 16 (second polysilicon layer), a silicon nitride film 17, a polysilicon layer 18, an inter-electrode insulating film (for example, three-layered laminated film) 9 and a tungsten layer 12 are sequentially formed on the element region 3 of the silicon substrate 1.

Further, a groove 22 which causes division of the tungsten layer 12 is formed on the end portion of the tungsten layer 12. An end-portion tungsten layer 12a obtained by performing the division using the groove 22 is connected to the polysilicon layer 18. A groove 23 which exposes the upper surface of the end portion of the polysilicon layer 16 is formed. Further, a groove 24 which exposes the upper surface of the element region 3 is formed. Here, an inter-layer insulating film SZ is formed in the grooves 22, 23, and 24.

Further, as shown in FIG. 30, a first contact 25 is formed on the upper surface of the central tungsten layer 12, and a second contact 26 is formed on the upper surface of the end-portion tungsten layer 14a. In addition, a third contact 27 is formed on the upper surface of the end-portion of the polysilicon layer 16, and a fourth contact 28 is formed on the upper surface of the end portion of the silicon substrate 1 (element region 3).

In a case of a capacitance element including the above configuration, a first capacitance element which includes the first contact 25 (tungsten layer 12), the second contact 26 (polysilicon layer 18) and the inter-electrode insulating film 9 is configured, and a second capacitance element which includes the second contact 26 (polysilicon layer 18), the third contact 27 (polysilicon layer 16) and the silicon nitride film 17 is configured, and a third capacitance element which includes the third contact 27 (polysilicon layer 16), the fourth contact 28 (silicon substrate 1 (element region 3)) and the gate oxide film 8′ are configured. In addition, if the first contact 25 and the third contact 27 are set to a common electrode 1 and the second contact 26 and the fourth contact 28 are set to a common electrode 2, it is possible to configure a capacitance element, which includes capacitance that is obtained by composing the capacitance of the first capacitance element, the capacitance of the second capacitance element, and the capacitance of the third capacitance element, between the common electrode 1 and the common electrode 2.

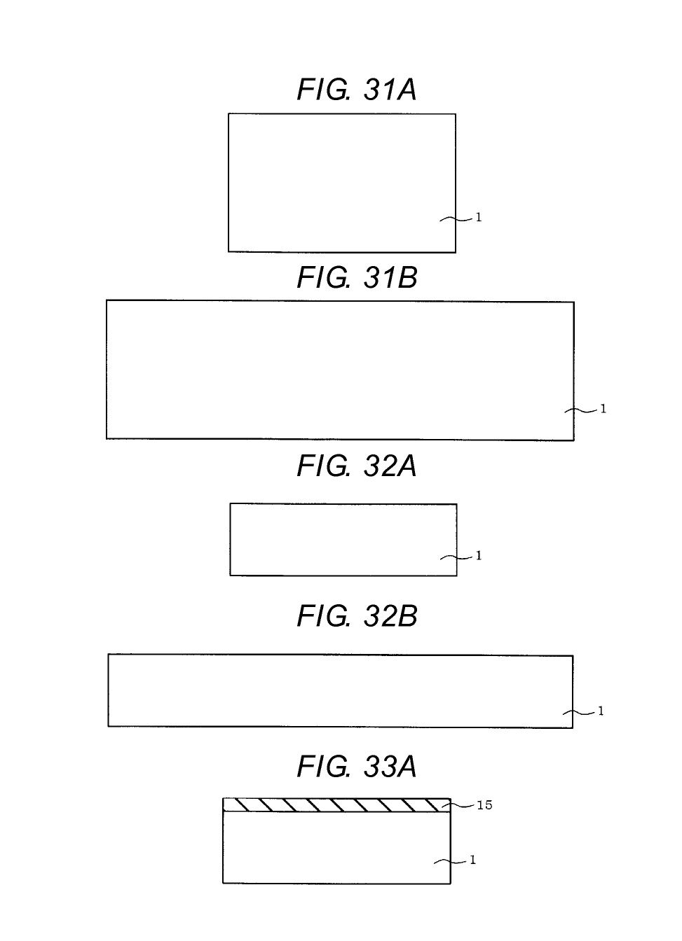

Subsequently, a manufacturing process to which the method of manufacturing a capacitance element including the above-described configuration is applied will be described with reference to FIGS. 31A to 50B. Also, FIGS. 31A to 50A are views schematically illustrating cross sections taken along the line A-A in FIG. 2 and are views illustrating cross sections including a structure corresponding to FIG. 28A. FIGS. 31B to 50B are views schematically illustrating cross sections taken along the line E-E in FIG. 29 and are views schematically illustrating the cross sections including a structure corresponding to FIG. 28B.

First, after the photoresist mask, in which a capacitance element forming region between the memory cell region and the peripheral circuit region is exposed, is formed on the silicon substrate 1 shown in FIGS. 31A and 31B using photolithography, the memory cell region and the capacitance element forming region of the silicon substrate 1 are etched. Therefore, configurations shown in FIGS. 32A and 32B are obtained.

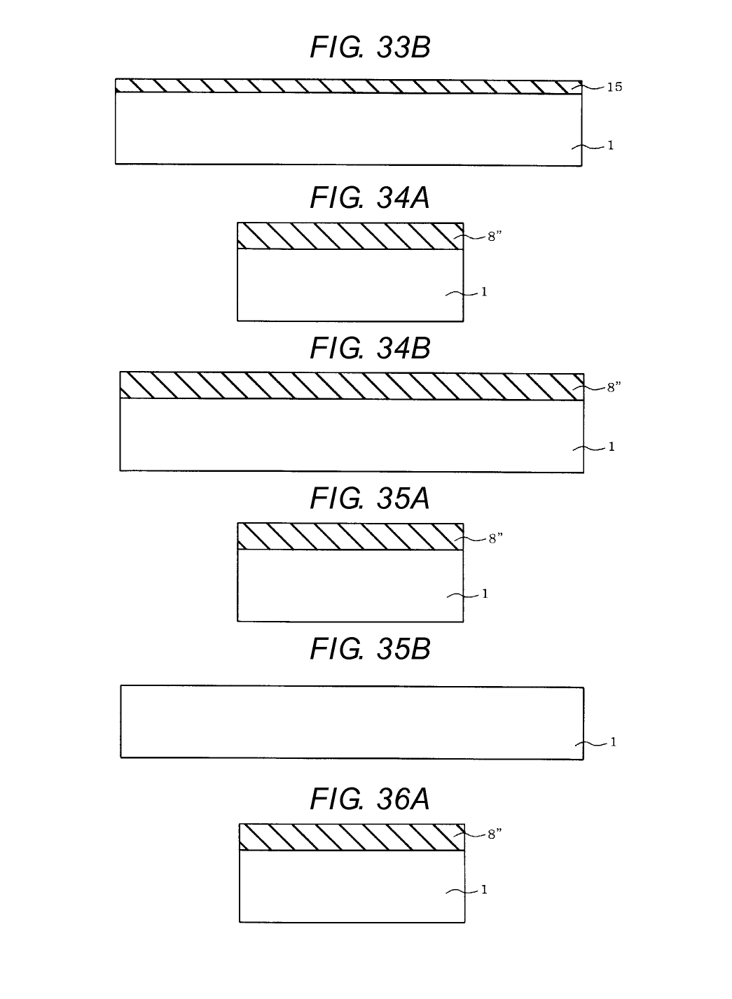

Subsequently, as shown in FIGS. 33A and 33B, a silicon oxide film 15 is formed on the upper surface of the silicon substrate 1 as a sacrificial layer. Thereafter, introduction of dopants is appropriately performed in order to form a well. Subsequently, the silicon oxide film 15 is detached, and the gate insulating film 8″, which is an oxide film 8″ buried in the memory cell region and which is the gate insulating film 8″ for the peripheral transistors of the high voltage system, is formed as shown in FIGS. 34A and 34B. A thermally-oxidized film is used as the gate insulating film 8″ in consideration of reliability. Also, an oxide film in a deposition system may be used as the gate insulating film 8″. In addition, the film thickness of the gate insulating film 8″ is set to, for example, 30 to 40 nm.

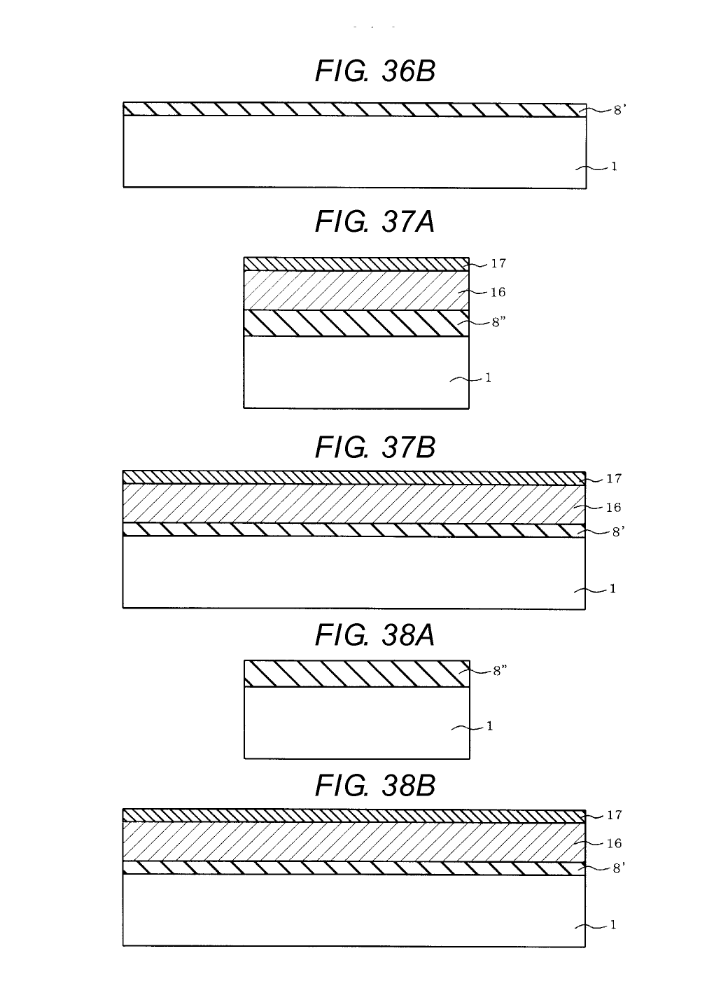

Subsequently, after the photoresist mask in which the capacitance element forming region of the peripheral circuit region is exposed, is formed using photolithography, the gate insulating film 8″ of the capacitance element forming region is etched and detached using, for example, dilute hydrofluoric acid-based WET etching. Therefore, a configuration shown in FIGS. 35A and 35B is obtained. Subsequently, the gate oxide film 8′ of the low voltage system is formed in the capacitance element forming region of the silicon substrate 1 using thermal oxidation as shown in FIGS. 36A and 36B.

Thereafter, as shown in FIGS. 37A and 37B, a polysilicon layer 16 which is the gate electrode in the peripheral circuit region on the gate insulating film 8′ or 8″ is formed, and a silicon nitride film 17 is formed on the polysilicon layer 16. Meanwhile, although the silicon nitride film 17 is a stopper in the process shown in FIGS. 19A to 19C, the silicon nitride film 17 is a part of the capacitance element in the capacitance element forming region. In this case, it is preferable to form the polysilicon layer 16 to be polysilicided in such a way as to, for example, form an amorphous silicon layer and then anneal the amorphous silicon layer. In addition, the polysilicon layer may be directly formed. Also, it is possible to implant boron, arsenic, or phosphorus into the polysilicon layer 16 to an extent such that the gate electrode is not depleted (for example, 1×10²⁰ cm⁻³ or greater).

Subsequently, as shown in FIGS. 38A and 38B, after the photoresist mask in which the memory cell region is exposed, is formed using photolithography, the silicon nitride film 17 and the polysilicon layer 16 in the memory cell region are etched and removed using, for example, the RIE. Thereafter, the upper portion of the oxide film 8″ with RIE damage is removed using, for example, WET etching. At this time, the silicon nitride film 17 is not removed by WET etching in the peripheral circuit region.

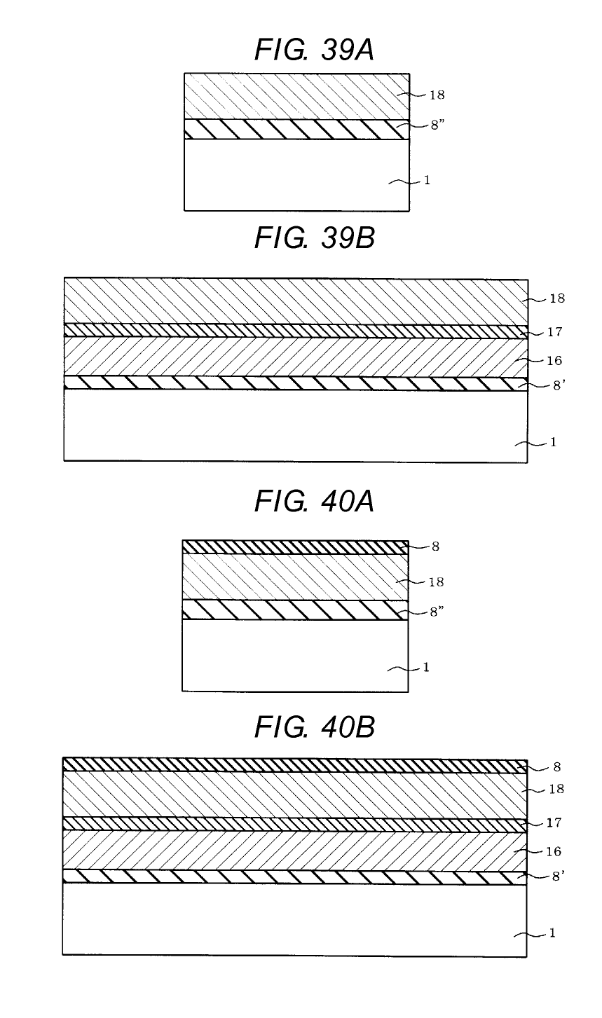

Thereafter, as shown in FIGS. 39A and 39B, a polysilicon layer 18 which is the channel region of the memory cell region is formed. It is preferable to form the polysilicon layer 18 to be polysilicided in such a way as to, for example, form an amorphous silicon layer and then anneal the amorphous silicon layer. In addition, the polysilicon layer may be directly formed. Further, in order to prevent current drive force from being lowered, the concentration of the dopants of the polysilicon layer 18 is set to be lower than the concentration of the dopants of the polysilicon layer 16 which is used as the gate electrode in the peripheral circuit region, and the grain size of the polysilicon of the polysilicon layer 18 is set to be greater than the grain size of the polysilicon of the polysilicon layer 16 which is used as the gate electrode in the peripheral circuit region. Further, in order to reduce an aspect ratio when the element isolation grooves in the memory cell region are processed and in order to improve the cut-off properties of the memory cell transistors, it is preferable to set the film thickness of the polysilicon layer 18 to, for example, 100 nm or less. Also, the height of the upper surface of the polysilicon layer 18 is included in a range that is, for example, 10 nm or less from the same plane.

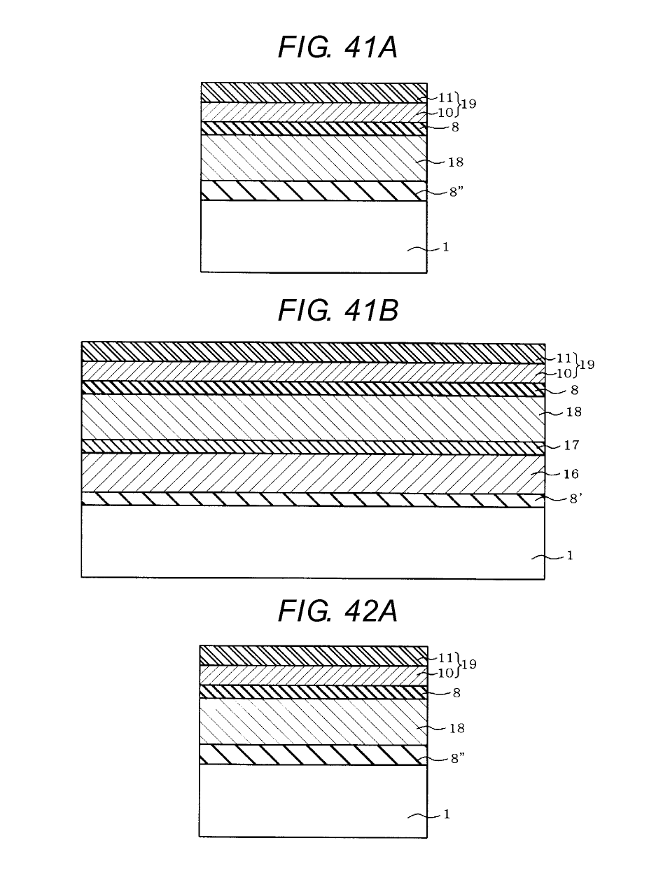

Subsequently, as shown in FIGS. 40A and 40B, the gate insulating film 8 is formed as a tunnel insulating film on the polysilicon layer 18. For example, the silicon oxide film or a laminated film which includes a silicon nitride film, a polysilicon film and a rare-earth oxide film may be used as the gate insulating film 8. Subsequently, as shown in FIGS. 41A and 41B, a charge storage layer 19 is formed on the gate insulating film 8. A polysilicon layer 10 with a film thickness of, for example, 6 to 8 nm and a trapped film 11 with a film thickness of, for example, 6 to 7 nm are laminated and formed as the charge storage layer 19. Instead of the polysilicon layer 10, a metallic layer including Ti, Ta, Mo or W or a laminated film, in which the polysilicon layer and the metallic layer including Ti, Ta, Mo, or W are laminated, may be used as the conductive layer. It is preferable to use a silicon nitride film or a hafnium oxide film as the trapped film 11.

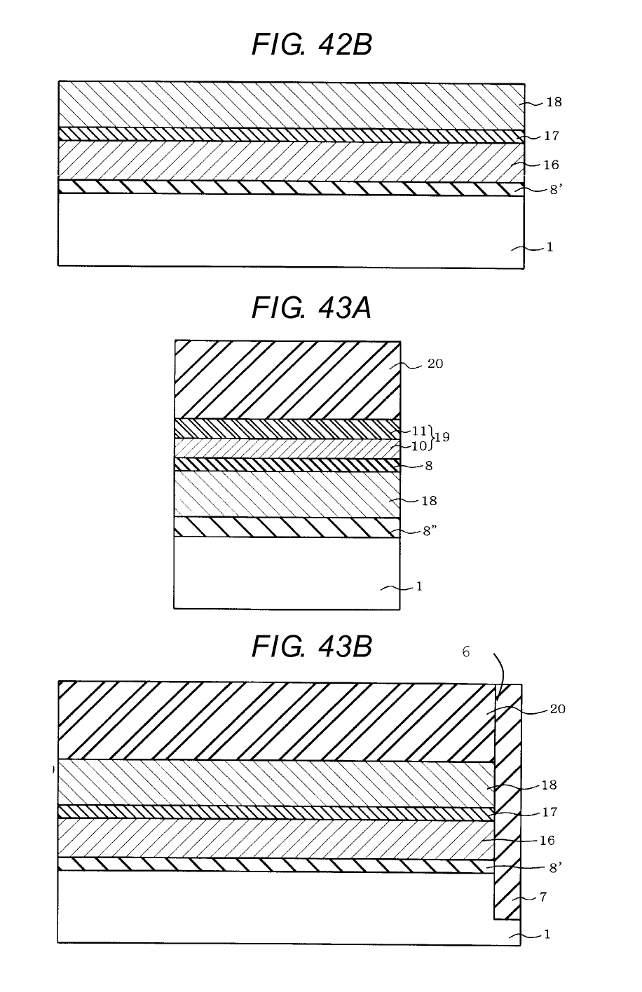

Thereafter, as shown in FIGS. 42A and 42B, after the photoresist mask in which the capacitance element forming region of the peripheral circuit region is exposed, is formed using photolithography, the charge storage layer 19 and the gate insulating film 8 in the capacitance element forming region are etched and removed using, for example, the RIE.

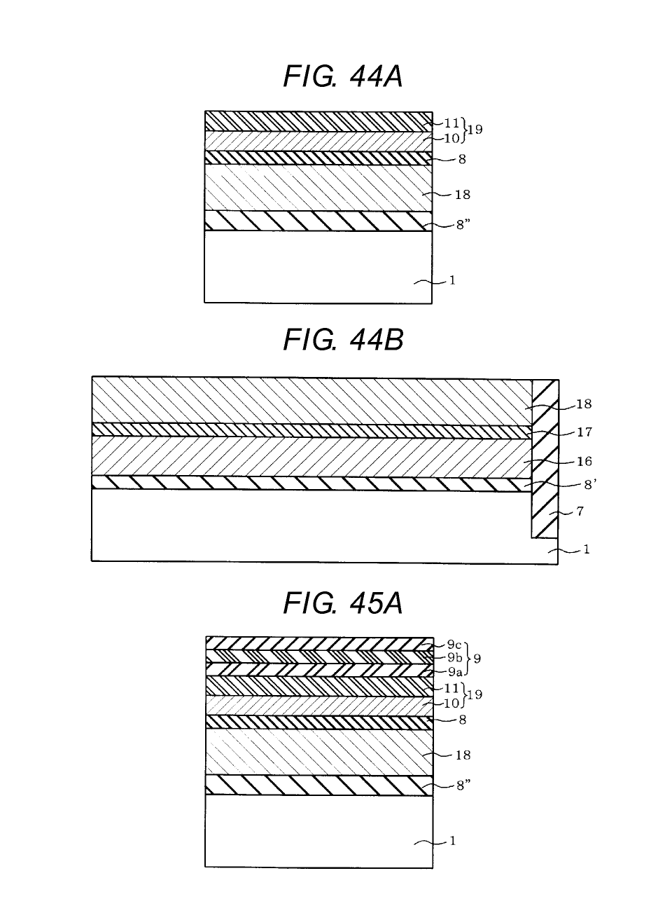

Subsequently, as shown in FIGS. 43A and 43B, a silicon nitride film 20 is formed as a mask material for processing the element isolation groove 6. Thereafter, a process of processing the element isolation groove 6 (refer to FIGS. 21A to 21C in the first embodiment), a process of burying the element isolation insulating film 7 in the element isolation groove 6 and performing planarization by using the silicon nitride film 20 as a stopper based on CMP (refer to FIGS. 22A to 22C in the first embodiment), and a process of etching back the upper portion of the element isolation insulating film 7 are performed. Subsequently, the silicon nitride film 20 is etched and removed using chemicals, and thus configurations shown in FIGS. 44A and 44B are obtained.

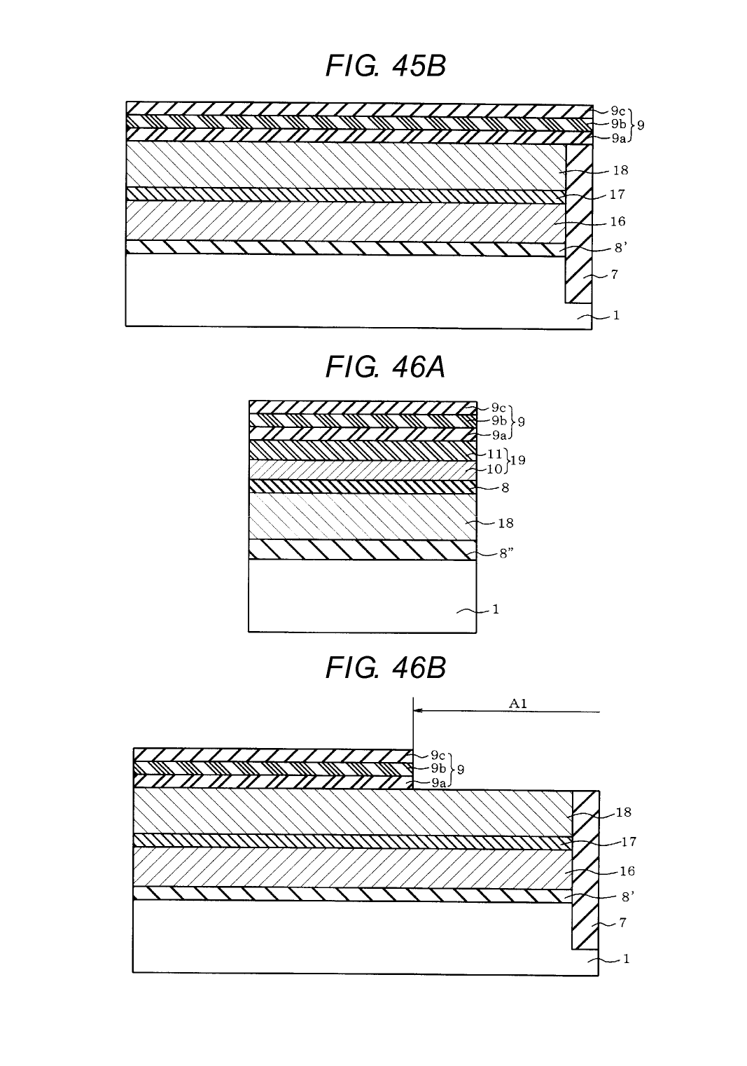

Thereafter, as shown in FIGS. 45A and 45B, the inter-electrode insulating film (block insulating film and the inter-poly insulating film) 9 is formed above the charge storage layer 19 in the memory cell region and the polysilicon layer 18 in the capacitance element forming region. In this case, for example, a three-layered laminated film (the silicon oxide film 9a, the silicon nitride film 9b, and the rare-earth oxide film 9c) is used as the inter-electrode insulating film 9.

Subsequently, as shown in FIGS. 46A and 46B, after the photoresist mask in which a partial region (a region indicated using reference numeral A1) of the capacitance element forming region is exposed, is formed using photolithography, the inter-electrode insulating film 9 in the partial region of the capacitance element forming region is etched and removed using, for example, the RIE method. Also, in this process, the inter-electrode insulating film 9 in the low voltage operation region and the high voltage system region of the peripheral circuit region is removed (refer to FIGS. 24B and 24C).

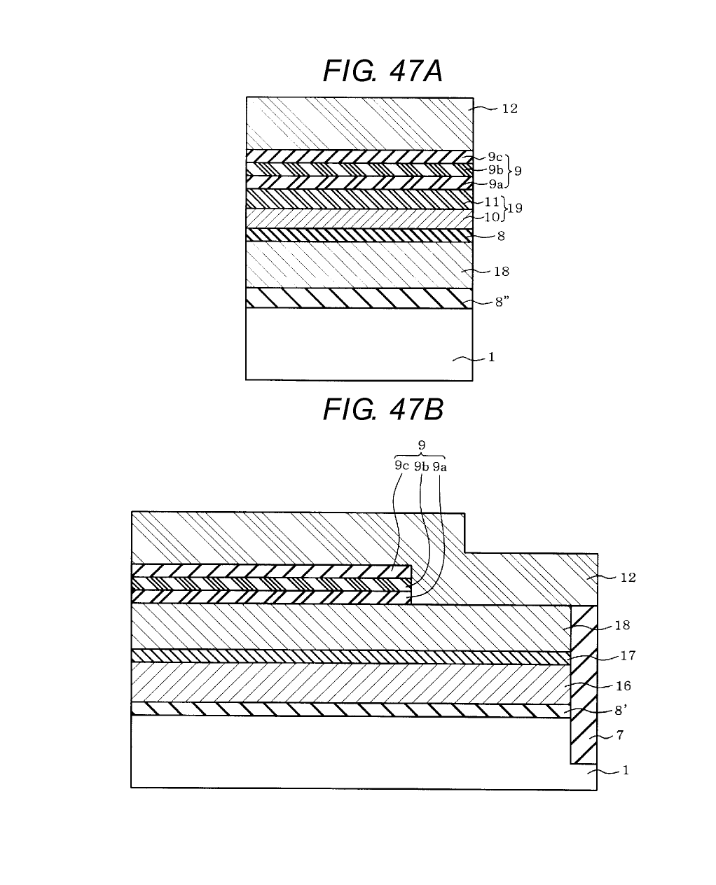

Subsequently, as shown in FIGS. 47A and 47B, a tungsten layer 12 is formed as a control gate electrode on the inter-electrode insulating film 9 and the polysilicon layer 18. Therefore, the tungsten layer 12 comes into contact with the polysilicon layer 18 in the A1 region of the capacitance element forming region.

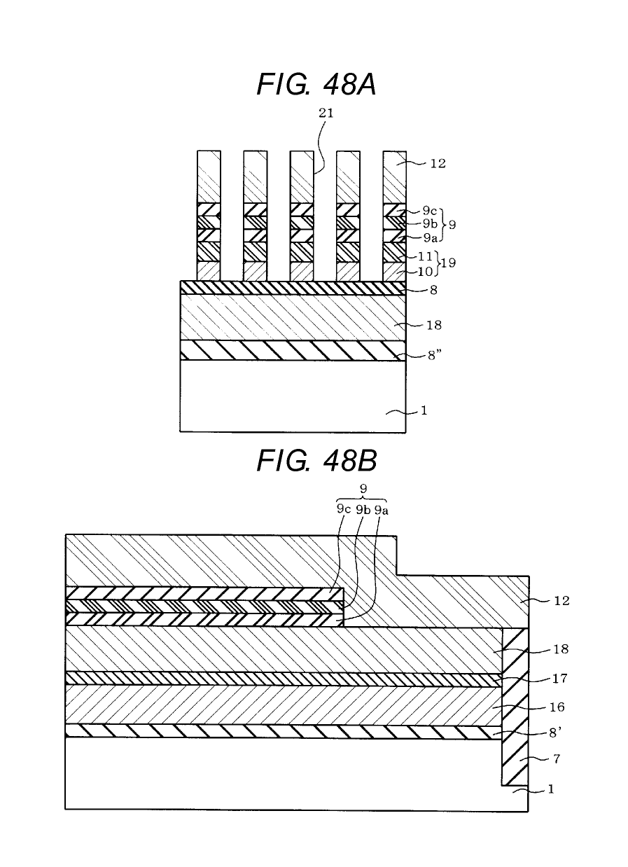

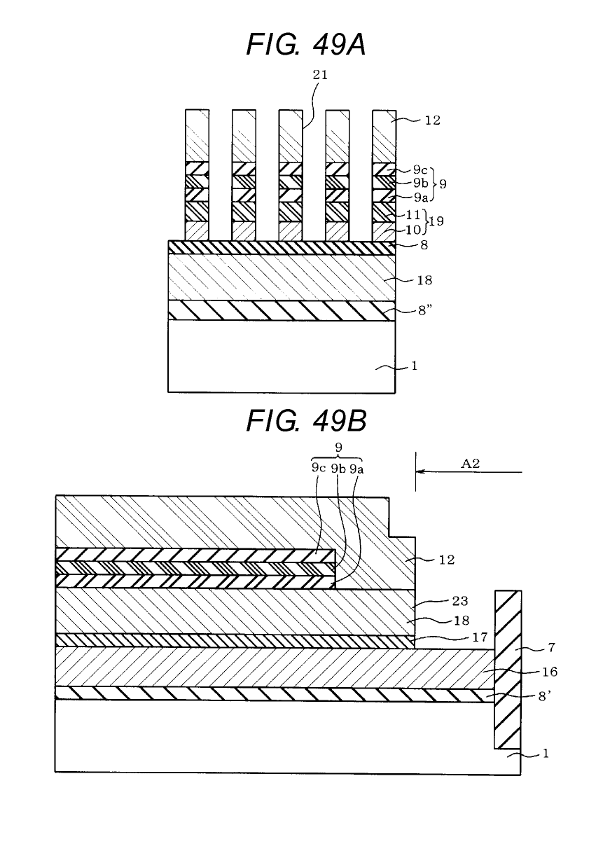

Subsequently, as shown in FIGS. 48A and 48B, the electrode separation groove 21 is formed by performing gate electrode process in the memory cell region and performing etching to the upper surface of the gate insulating film 8. Thereafter, as shown in FIGS. 49A and 49B, after the photoresist mask in which a partial region of the capacitance element forming region (a region indicated by reference numeral A2) is exposed, is formed using photolithography, a groove 23 is formed by etching the partial region of the capacitance element forming region to the upper surface of the polysilicon layer 16 using, for example, the RIE method, thereby exposing the upper surface of the end portion of the polysilicon layer 16. Also, in this process, the gates (not shown in the drawing) of the low voltage operation region and the high voltage operation region of the peripheral circuit region are processed at the same time. Meanwhile, at this time, the upper surface of the element isolation insulating film 7 may be etched at the same time.

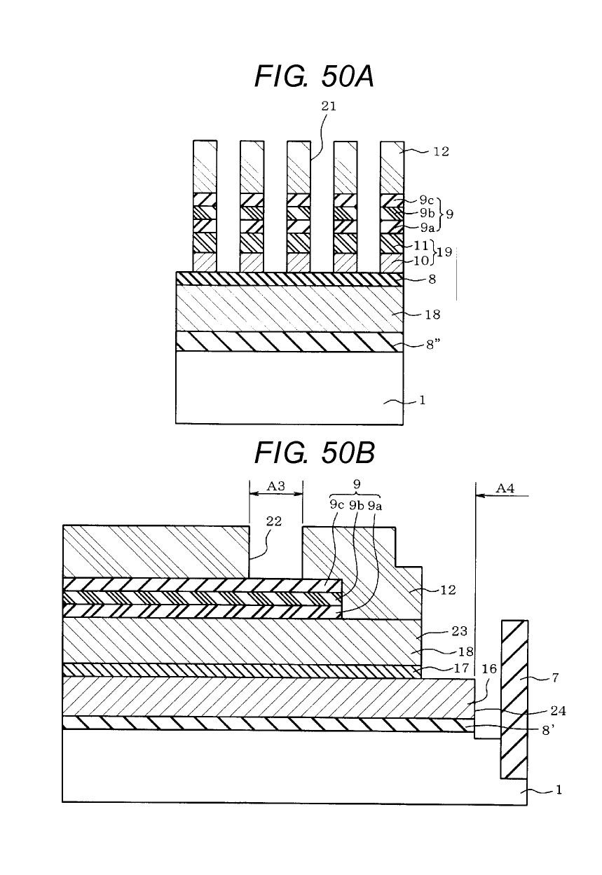

Subsequently, as shown in FIGS. 50A and 50B, after the photoresist mask in which the partial regions (regions indicated using reference numerals A3 and A4) of the capacitance element forming region are exposed, is formed using photolithography in order to separate electrodes in the capacitance element forming region, the grooves 22 and 24 are formed by etching the partial regions of the capacitance element forming region using, for example, the RIE, and thus the tungsten layer 12 is detached (that is, the groove is formed until the groove reaches at least the upper surface of the inter-electrode insulating film 9a) and the upper surface of the end-portion of the silicon substrate 1 (element region 3) is exposed. Meanwhile, at this time, the upper surface of the element isolation insulating film 7 may be etched at the same time. Thereafter, diffused layer introduction is performed using an ion implantation method, the inter-layer film is buried, and, the contacts 24, 25, 26, and 27 are formed and wired using the well-known method as shown in FIG. 30. As a result, it is possible to form three kinds of capacitance elements which are laminated in the capacitance element forming region. Meanwhile, since the forming regions of the contacts 24, 25, 26, and 27 or the regions for electrode separation are configured with considerably small areas compared to the entire area of the capacitance element forming region, it is possible to almost ignore the increase in the areas used to form the regions.

Configurations according to the second embodiment which are not described above are the same as the configurations according to the first embodiment. Accordingly, in the second embodiment, it is possible to obtain almost the same effect as in the first embodiment. In particular, according to the second embodiment, in the process of forming the memory cell transistors in the memory cell region, a laminated film structure, in which the gate insulating film 8′ (second insulating film), the polysilicon layer 16 (second polysilicon layer), the silicon nitride film 17, the polysilicon layer 18 (first polysilicon layer), the inter-electrode insulating film 9 and the tungsten layer 12 are laminated and formed in the peripheral circuit region. At the same time, it is possible to form the first capacitance element includes the polysilicon layer 18, the inter-electrode insulating film 9, and the tungsten layer 12. Thus it is possible to form the capacitance element in the peripheral circuit region of the NAND-type flash memory device which includes the SOI structure in which the polysilicon layer 18 is used as the element region 3.

Further, according to the second embodiment, the second capacitance element includes the polysilicon layer 16, the silicon nitride film 17 and the polysilicon layer 18 and the third capacitance element includes the silicon substrate 1, the gate insulating film 8′, and the polysilicon layer 16. Therefore, it is possible to laminate the three capacitance elements and it is possible to reduce the capacitance element forming area. Further, according to the second embodiment, it is possible to suppress increase in the number of processes while maintaining the configuration in which the capacitance elements are formed in the peripheral circuit region.

### Third Embodiment

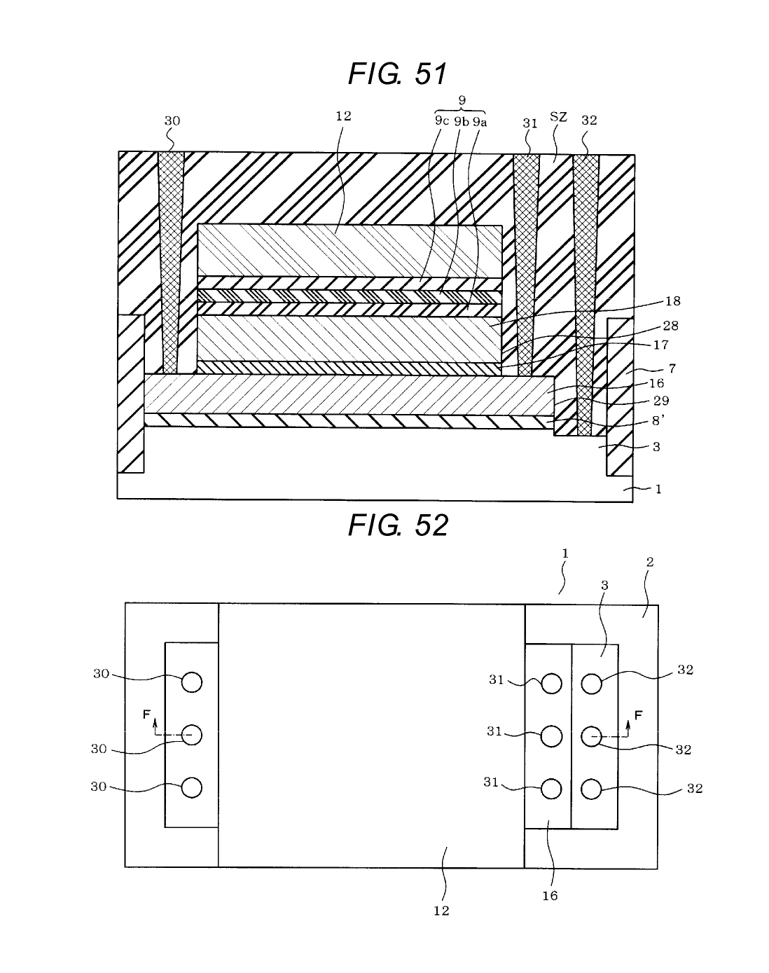

FIGS. 51 and 52 illustrate a third embodiment. Also, the same reference numerals are assigned to components which are the same in the first embodiment or the second embodiment. According to the third embodiment, in a process of forming memory cell transistors (components which are the same in the first embodiment) in a memory cell region, resistance elements are formed in peripheral circuit regions at the same time. FIG. 51 illustrates an example of a schematic cross-sectional configuration of the resistance elements. Further, FIG. 52 is an example of a plan view illustrating the layout pattern of the resistance elements. Also, FIG. 51 is a cross sectional view taken along a line F-F in FIG. 52.

As shown in FIGS. 51 and 52, an STI 2 is formed surrounding an element region 3 on a silicon substrate 1. On the element region 3 of the silicon substrate 1, a gate insulating film 8′, a polysilicon layer 16, a silicon nitride film 17, a polysilicon layer 18, an inter-electrode insulating film (for example, three-layered laminated film) 9 and a tungsten layer 12 are sequentially formed.

Further, a groove 28 is formed in the both end portions of each of the tungsten layer 12, the inter-electrode insulating film 9, the polysilicon layer 18, and the silicon nitride film 17, and thus the upper surfaces of the both end portions of the polysilicon layer 16 are exposed. In addition, a groove 29 is formed in one end portion of each of the polysilicon layer 16 and the gate insulating film 8′, and thus the upper surface of the silicon substrate 1 (element region 3) is exposed.

Further, a fifth contact 30 and a sixth contact 31 are formed on the upper surfaces of the both end portions of the polysilicon layer 16, and a seventh contact 32 is formed on the upper surface in one end portion of the silicon substrate 1. In this case, a resistance element is configured between the fifth contact 30 and the sixth contact 31. Also, since a method of manufacturing the resistance element including the above-described configuration is almost the same as the above-described method of manufacturing the capacitance element, the description thereof will not be repeated.

Configurations according to the third embodiment which are not described above are the same as the configurations according to the first embodiment or the second embodiment. Accordingly, in the third embodiment, it is possible to obtain almost the same effect as in the first embodiment or the second embodiment. In particular, in the process of forming the memory cell transistors in the memory cell region according to the third embodiment, it is possible to form the resistance element in the peripheral circuit region at the same time. In the resistance element including the above-described configuration, it is possible to adjust the magnitude of a resistance value by controlling the concentration of the dopants which are implanted in the polysilicon layer 16.

### Fourth Embodiment

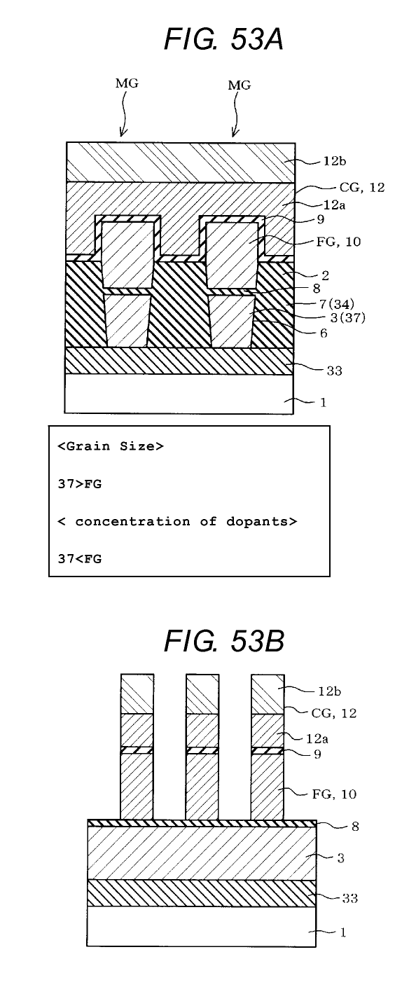

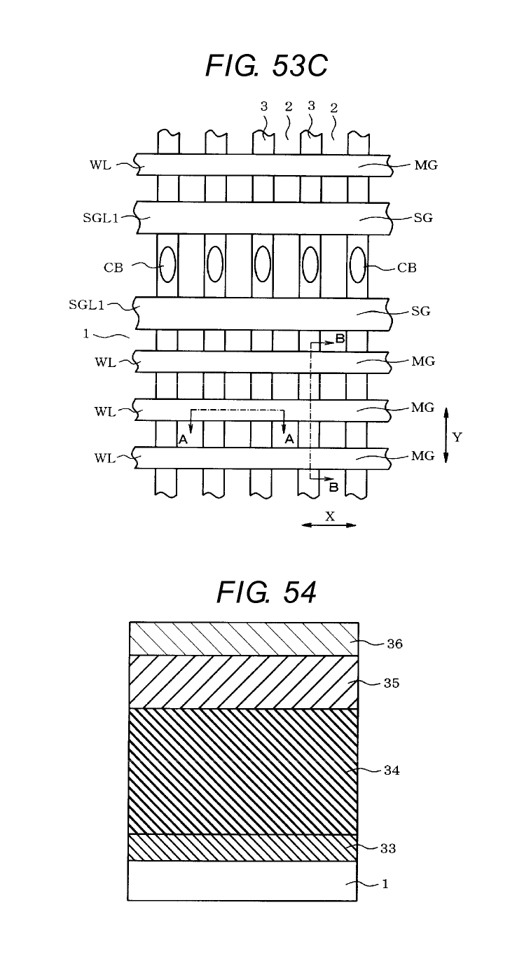

FIGS. 53A to 62 illustrate a fourth embodiment. Also, the same reference numerals are assigned to components which are the same in the first embodiment. First, the structure of the gate electrode of a memory cell transistor in a memory cell region according to the fourth embodiment will be described with reference to FIGS. 53A to 53C. FIG. 53A is a view schematically illustrating a cross section taken along a line A-A (the word line direction and the X direction) in FIG. 53C, FIG. 53B is a view schematically illustrating a cross section taken along a line B-B (the bit line direction and the Y direction) in FIG. 53C, and FIG. 53C shows an example of a schematic plan view illustrating the layout pattern of a part of the memory cell region according to the fourth embodiment.

As shown in FIG. 53A and FIG. 53B, a silicon nitride film (insulating film) 33 used as the stopper in a damascene process which will be described later is formed on the upper surface of a silicon substrate 1, and element regions 3 are formed on a silicon nitride film 33 in the X direction via an element isolation groove 6 while the element regions 3 are separated from each other. For example, a polysilicon film is used as the element region 3. An element isolation insulating film 7, which uses a silicon oxide film, is formed in the element isolation groove 6 and constitutes an element isolation region (STI) 2.

A memory cell transistor Trm includes a gate insulating film 8 which is formed on the element region 3, a gate electrode MG which is provided above the gate insulating film 8, and a diffused layer (not shown in the drawing) which is formed in the element region 3. The gate electrode MG includes a floating gate electrode FG which functions as a charge storage layer, an inter-electrode insulating film 9 which is formed above the floating gate electrode FG, and a control gate electrode CG which is formed on the inter-electrode insulating film 9. The diffused layer is positioned and formed on the both sides of the gate electrode MG of the memory cell transistor on the surface layer of the element region 3, and constitutes the source and drain regions of the memory cell transistor.

The gate insulating film 8 is a film which is called a tunnel insulating film and, for example, a silicon oxide film is used. For example, a polysilicon layer (conductive layer) is used as the floating gate electrode FG. The inter-electrode insulating film 9 functions as an inter-poly insulating film, an inter-conductive layer insulating film, and an inter-electrode insulating film. It is preferable to use, a single layer film or a laminated film of, for example, the silicon oxide film, the silicon nitride film, and the film which includes a rare-earth oxide as the inter-electrode insulating film 9. The control gate electrode CG includes a conductive layer 12 which functions as the word line WL for the memory cell transistors. For example, a laminated layer in which a polysilicon layer 12a and a tungsten (W) layer 12b are laminated is used as the conductive layer 12. Also, for example, a single layered-tungsten (W) layer may be used as the conductive layer 12, and a film including a structure in which the polysilicon layer and a silicide layer silicided by any one of metals, such as tungsten (W), cobalt (Co), and nickel (Ni), formed on the polysilicon layer are laminated, may be used. Further, all of the conductive layer 10 may be configured with the silicide layer (that is, silicide layer alone).

Here, in the structure of the gate electrode in the cross section in the word line direction, as shown in FIG. 53A, the width dimension of the upper portion of the polysilicon layer of the element region 3 is configured to be greater than the width dimension of the lower portion thereof. The element region 3 is configured to have a taper shape from the upper portion to the lower portion. Therefore, the depletion layer of the channel region is easily extended, and thus it is possible to improve channel boost when non-selected write is performed and to suppress erroneous write. Further, in the cross section in the word line direction, the width dimension of the upper end-portion of the polysilicon layer of the element region 3 is configured to be less than the width dimension of the lower end-portion of the floating gate electrode FG (charge storage layer). Therefore, it is possible to improve the controllability of the channel from the gate. Such improvement in controllability of the gate is important to improve the sub-threshold characteristics of the memory cell in recent NAND-type flash memory devices in which the length of a gate is equal to or less than 30 nm.

In addition, in the cross section in the word line direction, the inclination of the side surface of the portion of the floating gate electrode FG, which is buried in the element isolation insulating film 7 is greater than the inclination of the side surface of the portion of the floating gate electrode FG, which is exposed from the element isolation insulating film 7. Therefore, the corner of the upper portion of the floating gate electrode FG is not sharply-angled. As a result, it is possible to relieve the electric field concentration of the inter-electrode insulating film 9 between the corner of the upper portion of the floating gate electrode FG and the control gate CG, and it is possible to prevent the inter-electrode insulating film from being electrically damaged.

In addition, as shown in FIG. 53B, the gate electrodes MG of memory cell transistors are provided in parallel in the Y direction, and are electrically separated from each other. An inter-memory cell insulating film (not shown in the drawing) is formed between the gate electrodes MG. For example, a silicon oxide film using Tetraethyl Orthosilicate (TEOS) or a low-dielectric insulating film is used as the inter-memory cell insulating film. Also, for example, an air gap may be provided between the gate electrodes MG. For example, a liner insulating film (not shown in the drawing) which includes the silicon nitride film is formed on the inter-memory cell insulating film and the control gate electrode CG, and, for example, an inter-layer insulating film (not shown in the drawing) which includes the silicon oxide film is formed on the liner insulating film.

Subsequently, when a NAND-type flash memory device which includes the above-described configuration is manufactured, a manufacturing process to which the manufacturing method according to the embodiment is applied will be described with reference to FIGS. 54 to 62. Also, FIGS. 54 to 62 are views schematically illustrating cross sections taken along a line A-A in FIG. 53C and are cross sectional views illustrating a structure corresponding to FIG. 53A.

First, as shown in FIG. 54, a silicon nitride film 33 used as a stopper for a damascene process which will be performed later is formed on a silicon substrate 1, and a silicon oxide film 34 as an element isolation insulating film 7 which will be used later is formed thereon. The film thickness of the silicon oxide film 34 is set such that the film thickness is almost equal to the sum of the film thickness of an element region 3 (channel region), a gate insulating film 8, a charge storage layer 19 and an inter-electrode insulating film 9. Further, a silicon nitride film 35 and a silicon oxide film 36 as mask materials are formed on the silicon oxide film 34.

Subsequently, as shown in FIG. 55, a photoresist mask having an opening to form the element region 3 (channel region) is formed using photolithography. Then, an etching process is performed, for example, by RIE, and the channel forming region is processed by using the lowest silicon nitride film 33 as a stopper. Also, since the silicon nitride film 33 which is positioned immediately above the silicon substrate 1 is used as the stopper when the process is performed, the silicon nitride film is not necessarily used and the silicon oxide film may be used in a range in which the controllability of the process depth of the silicon oxide film is permitted. Here, a process is performed under a condition that an opening TP includes a reverse taper shape in which the width thereof becomes wide from the bottom to the top.

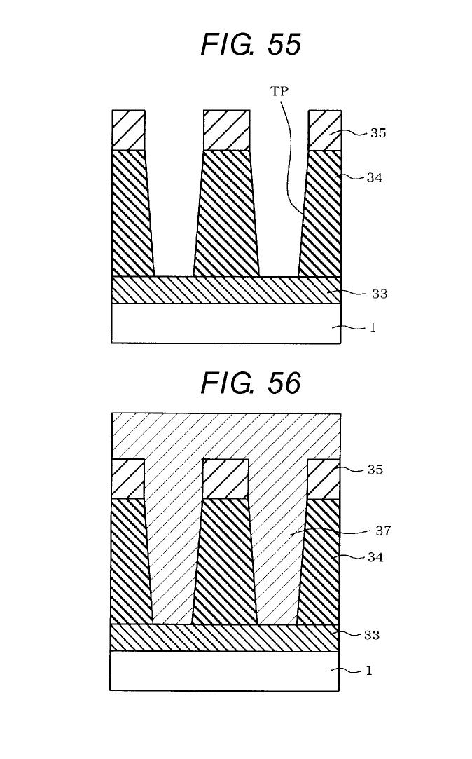

Thereafter, as shown in FIG. 56, the polysilicon layer 37 as the channel region is formed in the opening TP. Then, annealing is performed. The grain of the polysilicon layer 37 grows and becomes large by the annealing. Here, N₂ annealing is performed at a temperature from 500° C. to 800° C. It is preferable for the temperature to be high for electron mobility in order to secure driving current in the channel region. When the grain size of the polysilicon is increased, the electron mobility of the polysilicon is high. So, it is preferable to use annealing conditions which are appropriate to make the grain size be large. Also, the annealing conditions are not required for the polysilicon layer of the charge storage layer. In addition, an amorphous silicon film may be formed instead of the polysilicon layer 37 being formed.

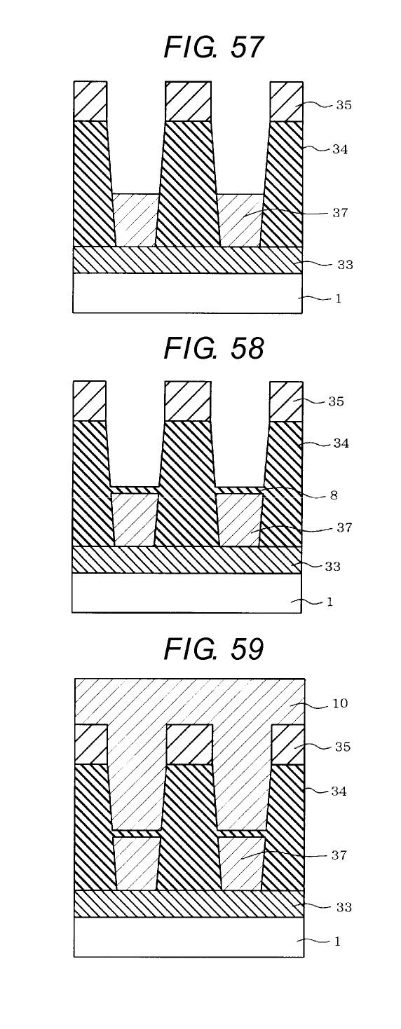

Subsequently, as shown in FIG. 57, etching-back is performed on the polysilicon layer 37 until the polysilicon layer 37 has a certain thickness for the channel layer. As a result, a taper shape in which the width dimension of the upper portion of the polysilicon layer 37 is greater than the width dimension of the lower portion is obtained. Further, as shown in FIG. 58, the gate insulating film 8 is formed above the polysilicon layer 37 using an oxidation process, such as thermal oxidation or SPA oxidation.

Thereafter, as shown in FIG. 59, the polysilicon layer 10 which is a charge storage layer (floating gate electrode FG) is formed on the gate insulating film 8 in the opening TP. Since the opening TP has the reverse taper shape, the width dimension of the upper end-portion of the polysilicon layer in the active region 3 is smaller than the width dimension of the lower end-portion of the polysilicon layer. In addition, the polysilicon layer 10 includes the concentration of the dopants which is considerably high, that is, 10²⁰ or greater, and is configured to have smaller grain size than that of the polysilicon layer 37 in the channel region. With such a configuration, it is possible to prevent coupling loss generated because the charge storage layer is depleted. Meanwhile, the polysilicon layer 10 of the charge storage layer does not acquire high electron mobility unlike the channel region, and thus it is possible to cause the concentration of the dopants to be high.

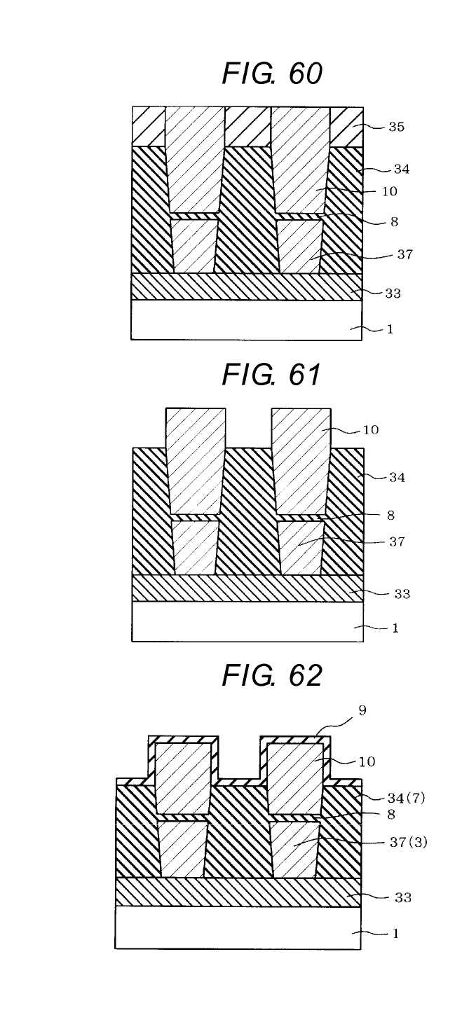

Subsequently, as shown in FIG. 60, the polysilicon film 10 is planarized using CMP in such a way that the silicon nitride film 35 is used as a stopper. Subsequently, as shown in FIG. 61, for example, the silicon nitride film 35 is removed using hot phosphoric acid, and thus the upper surface and the side surfaces of the polysilicon layer 10 of the charge storage layer are exposed.

Thereafter, as shown in FIG. 62, an inter-electrode insulating film 9 is formed on the silicon oxide film 34 and the upper surface and the side surfaces of the polysilicon layer 10 which is the charge storage layer. Further, as shown in FIG. 53A, a conductive layer 12 (a polysilicon layer 12a and a tungsten layer 12b) is formed as a control gate electrode CG on the inter-electrode insulating film 9. Thereafter, the NAND-type flash memory device is manufactured through each of the processes, such as a normal gate process, a diffused layer formation, an inter-layer insulating film burial, contact formation, and upper portion metal wiring.

The configurations according to the fourth embodiment which are not described are the same as the configurations according to the fourth embodiment. Therefore, it is possible to obtain almost the same effect as in the first embodiment in the fourth embodiment. In particular, according to the fourth embodiment, the polysilicon layer 37 (first polysilicon layer) as the channel region is formed on the silicon nitride film 33 (first insulating film), and the width dimension in the direction along the word line of the lower end-portion of the polysilicon layer 37 is configured to be smaller than the width dimension in the direction along the word line of the upper end-portion of the polysilicon layer 37. Therefore, it is easy for the depletion layer of the channel region to be extended, and thus it is possible to improve channel boost when non-selected write is performed and to suppress erroneous write. In addition, since the width dimension in the direction along the word line of the upper end-portion of the polysilicon layer 37 is configured to be smaller than the width dimension in the direction along the word line of the lower end-portion of the polysilicon layer 10 (charge storage layer), it is possible to improve the controllability of the channel from the gate.

In addition, in the fourth embodiment, since the damascene process of burying the channel region (polysilicon layer 37) and the charge storage layer (polysilicon layer 10) is used after the process is performed, it is possible to prepare a structure, in which the width dimension of the lower end is smaller than the width dimension of the upper end of the channel region and the width dimension of the lower end of the charge storage layer is greater than the width dimension of the upper end of the channel region, using self-alignment.

In addition, in the fourth embodiment, the gate insulating film 8 (tunnel oxide film) is configured to be formed after the element isolation region is processed. Therefore, it is possible to suppress damage to the tunnel oxide film using dry etching for processing the element isolation groove, and thus to improve reliability such as the charge retention characteristics rather than the charge storage layer is formed after the gate insulating film 8 (tunnel oxide film) is formed.

Further, when the etching of the element isolation insulating film (SiO₂) is performed using the RIE method, the areas of contacts with the charge storage layer of the inter-electrode insulating film may vary due to variation in etching. Then, it leads to variation in write characteristics. In contrast, according to the fourth embodiment, etching is not performed on the element isolation insulating film (SiO₂) and a distance between a top surface of the polysilicon layer 10 and top surface of the silicon oxide film 34 in FIG. 53A is determined by the film thickness of the silicon nitride film 35 (stopper film). Then, it is possible to reduce variation in the amount of etching and it is possible to reduce the variation in the write characteristics.

### Fifth Embodiment

FIGS. 63A and 63B illustrate a fifth embodiment. Also, the same reference numerals are assigned to the same configurations as in the fourth embodiment. In the fifth embodiment, the gate electrode structure according to the fourth embodiment is the so-called a flat cell structure. More specifically, a laminated film in which a polysilicon layer 39 and a thin metal layer 40 are laminated is used instead of the polysilicon layer 10 as the floating gate electrode FG (charge storage layer) according to the fourth embodiment. Further, the height of the upper surface of the metal layer 40 is configured to be almost the same as the height of the upper surface of the silicon oxide film 34 (element isolation insulating film 7).

Configurations of the fifth embodiment which are not described above are the same as the configurations of the fourth embodiment. Accordingly, it is possible to obtain almost the same effect as in the fourth embodiment in the fifth embodiment. More specifically, since the gate electrode structure is a flat cell structure according to the fifth embodiment, it is possible to reduce the aspect ratio of the gate electrode and it is possible to further prevent pattern deformation from occurring.

### Sixth Embodiment

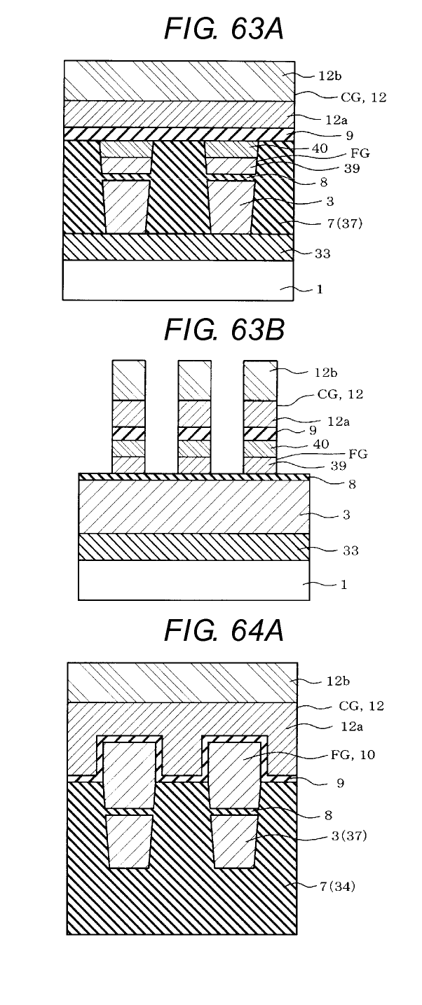

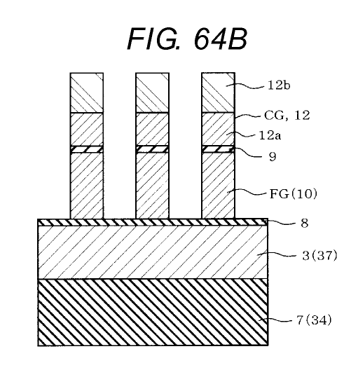

FIGS. 64A and 64B illustrate a sixth embodiment. Also, the same reference numerals are assigned to components which are the same in the fourth embodiment. In the sixth embodiment, a groove is formed in order to bury the lower portions of an element region 3 and a floating gate electrode FG (polysilicon layer 10) into a silicon oxide film 34 which is an element isolation insulating film 7 instead of forming a silicon nitride film 33 as a stopper in a damascene process. When a configuration is made such that a memory cell structure according to the sixth embodiment is laminated with two or more layers in the direction which is perpendicular to the principal plane of a silicon substrate, it is possible to use a memory cell structure including such a configuration as a memory cell structure on a layer which is higher than a second layer from the bottom. Also, configurations which are not described in the sixth embodiment are the same configurations according to the fourth embodiment. Therefore, it is possible to obtain almost the same effect as in the fourth embodiment in the sixth embodiment.

### Other Embodiments

In addition to the above-described plurality of embodiments, configurations may be used as follows:

In each of the above embodiments, a NAND-type flash memory device is applied. However, embodiments are not limited thereto and may be applied to another semiconductor device.

As described above, according to the semiconductor device of the embodiments, configurations in which an active region including a fine width is formed to achieve high integration, are provided, mechanical strength is increased, and thus it is possible to prevent the collapse or twist of a pattern in the active region from occurring.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor substrate;
a first insulating film that is formed on a memory cell region of the semiconductor substrate;
a first polysilicon layer that is formed on the first insulating film;
memory cell transistors that are formed on the first polysilicon layer with a gate insulating film interposed therebetween, each memory cell transistor having a first laminated structure including a charge storage layer, an inter-electrode insulating film and a control gate electrode; and
a second laminated structure that is formed on a peripheral circuit region of the semiconductor substrate and includes a second insulating film, a second polysilicon layer, a third insulating film, a third polysilicon layer, a fourth insulating film, and a first electrode,
wherein the third polysilicon layer, the fourth insulating film, and the first electrode are arranged to form a first capacitance element,
the fourth insulating film and the inter-electrode insulating film being formed from the same material, and the first electrode and the control gate electrode being formed from the same material.

2. The device according to claim 1, wherein the second polysilicon layer, the third insulating film, and the third polysilicon layer are arranged to form a second capacitance element.

3. The device according to claim 2, wherein the third polysilicon layer is formed from the same material as the first polysilicon layer.

4. The device according to claim 2, wherein the first electrode is a first part of a tungsten layer, and a second part of the tungsten layer is electrically isolated from the first part and in electrical contact with the third polysilicon layer.

5. The device according to claim 2, wherein the semiconductor substrate, the second insulating film, and the second polysilicon layer are arranged to form a third capacitance element.

6. The device according to claim 1, wherein the inter-electrode insulating film comprises a multi-layered structure.

7. The device according to claim 6, wherein the multi-layered structure comprises layers of silicon oxide film, silicon nitride film, and a rare-earth oxide film.

8. A semiconductor device comprising:
a semiconductor substrate;
a first insulating film that is formed on a memory cell region of the semiconductor substrate;
a first polysilicon layer that is formed on the first insulating film;
memory cell transistors that are formed on the first polysilicon layer with a gate insulating film interposed therebetween, each memory cell transistor having a first laminated structure including a charge storage layer, an inter-electrode insulating film and a control gate electrode; and
a second laminated structure that is formed on a peripheral circuit region of the semiconductor substrate and includes a second insulating film, a second polysilicon layer, a third insulating film, a third polysilicon layer, a fourth insulating film, and a first electrode,
wherein the first polysilicon layer is doped to form a resistance element having a desired electrical resistance,
the fourth insulating film and the inter-electrode insulating film being formed from the same material, and the first electrode and the control gate electrode being formed from the same material.

9. The device according to claim 8, further comprising a capacitance element, wherein the capacitance element includes the semiconductor substrate, the second insulating film, and the second polysilicon layer.

10. The device according to claim 8, wherein the inter-electrode insulating film comprises a multi-layered structure.

11. The device according to claim 10, wherein the multi-layered structure comprises layers of silicon oxide film, silicon nitride film, and a rare-earth oxide film.

12. The device according to claim 8, wherein the third polysilicon layer is formed from the same material as the first polysilicon layer.

13. A semiconductor device comprising:
a semiconductor substrate;
a first insulating film that is formed on a memory cell region of the semiconductor substrate;
a first polysilicon layer that is formed on the first insulating film; and
memory cell transistors that are formed on the first polysilicon layer with a gate insulating film interposed therebetween, each memory cell transistor having a charge storage layer, an inter-electrode insulating film and a control gate electrode,
wherein a width dimension of a lower end portion of the first polysilicon layer in a word line direction is smaller than a width dimension of an upper end portion of the first polysilicon layer in the word line direction.

14. The semiconductor device according to claim 13, wherein the width dimension of the first polysilicon layer in the direction along the word line continually decreases along a depth dimension thereof.

15. The device according to claim 13, wherein the width dimension of the upper end portion of the first polysilicon layer in the word line direction is smaller than a width dimension of a lower end portion of the charge storage layer in the word line direction.

16. The device according to claim 15, wherein the width dimension of the lower end portion of the charge storage layer in the word line direction is smaller than a width dimension of an upper end portion of the charge storage layer in the word line direction.

17. The semiconductor device according to claim 16, wherein the width dimension of the charge storage layer in the word line direction is constant at an upper portion thereof and is tapered at a lower portion thereof.

18. The device according to claim 13,
wherein the charge storage layer includes a third polysilicon layer,
wherein a grain size of the first polysilicon layer is greater than a grain size of the third polysilicon layer, and
wherein a concentration of dopants of the first polysilicon layer is smaller than a concentration of dopants of the third polysilicon layer.

19. The device according to claim 18,
wherein a silicon nitride film or a silicon oxide film is formed between the first polysilicon layer and the semiconductor substrate.

20. The device according to claim 13,
wherein an inclination of a side wall surface of a lower portion of the charge storage layer, which is buried in an element isolation insulating film, is greater than an inclination of a side wall surface of an upper portion of the charge storage layer which is exposed from the element isolation insulating film.
